(19) United States
(12) Patent Application Publication
(10) Pub. No.: US 2024/0424530 A1
(43) Pub. Date: Dec. 26, 2024

(54) MULTI-CHANNEL MEMS ACOUSTIC-BASED DIGITAL ISOLATOR DEVICES AND METHODS

(71) Applicants: HAMID SADRIMANESH, MONTREAL (CA); YVES BLAQUIÈRE, MONTREAL (CA); FRÉDÉRIC NABKI, MONTREAL (CA)

(72) Inventors: HAMID SADRIMANESH, MONTREAL (CA); YVES BLAQUIÈRE, MONTREAL (CA); FRÉDÉRIC NABKI, MONTREAL (CA)

(21) Appl. No.: 18/751,582

(22) Filed: Jun. 24, 2024

Related U.S. Application Data
(60) Provisional application No. 63/509,825, filed on Jun. 23, 2023.

(51) Int. Cl. B06B 1/06

(52) U.S. Cl. CPC B06B 1/0611

(57) ABSTRACT

Digital isolators in heterogenous system-in-package solutions are important devices for overcoming the challenge of managing the multiple voltage domains with different ground references. However, electronic digital isolators may be limited in their temperature range or be susceptible to electrostatic/electromagnetic fields which inherently result in electromagnetic interference. Micro-electromechanical systems (MEMS) based resonators are not susceptible to electromagnetic interference and through different materials can provide increased temperature operation. Accordingly, digital isolators exploiting vertical, lateral or side-by-side MEMS resonators to generate and receive acoustic waves, such as bulk acoustic waves, are outlined to provide such digital isolators.

### CROSS-REFERENCE TO RELATED APPLICATIONS

This patent claims the benefit of priority to U.S. Provisional Patent Application 63/509,825 filed Jun. 23, 2023; the entire contents of which are incorporated herein by reference.

### FIELD OF THE INVENTION

This patent application relates to digital isolators and more particularly to methods and devices for implementing digital isolators employing stackable multi-channel MEMS-based acoustic transmitters and receivers.

### BACKGROUND OF THE INVENTION

The advent of system-in-packages (SiP) technologies allows for compact, high speed, and low power in a variety of systems including, but not limited to, civil or military transportation systems, industrial automation systems, motor drives, medical equipment, solar inverters, power supplies, hybrid electric vehicles, and electric vehicles.

A heterogeneous high-density SiP may, for example, integrate discrete components and bare dice into a substrate interposer, an intermediate layer within device packaging used for interconnection routing or as a ground/power plane for example. This substrate interposer (substrate) may be in the form of a printed circuit board (PCB), low-temperature co-fired ceramic (LTCC), or silicon for example. Some power SiP applications embed multiple circuit designs and/or circuit technologies with different voltage levels and domains. Digital isolators in such a heterogenous SiP are important devices for overcoming the challenge of managing the multiple voltage domains with different ground references.

A digital isolator allows for the transmission of information between two power domains without any conductor between them. These can protect circuits against the danger of voltage spikes and ground loops between low and high-voltage domains (areas). Digital isolators solve this problem by defining two different ground references to the corresponding transmitter (Tx) and receiver (Rx) lines, ensuring reliable and safe communications between them. Transferring and receiving data happens through a medium between Tx and Rx utilizing one or more physical effects such as electromagnetics, electrostatics, or mechanical movements like pressure waves.

Micro-electromechanical systems (MEMS) provide an opportunity to build mechanical structures at the micro-scale. MEMS based resonators that produce acoustic waves are used for different applications, like real-time material study, gas detection systems, non-destructive testing, and medical imaging. Digital isolators can be implemented as a configuration that utilizes acoustic waves in any format, such as produced by capacitive resonators or piezoelectric resonators. The piezoelectric crystal for galvanic isolation was first introduced in 2004 for isolation in feedback lines in power electronic system design. The main advantages are a high isolation breakdown voltage due to the usage of a ceramic piezoelectric and the absence of electrostatic/electromagnetic fields, which inherently result in no electromagnetic interference.

Recently, Heller et al. in “CMUT Technology applied to galvanic isolation: theory and experiments” (IEEE Intl. Ultrasonics Symp. 2015, pp. 1-4) proposed two similar arrays of capacitive micromachined ultrasonic transducers (CMUTs) distributed on the surface of two dice that are connected back-to-back by wafer bonding. A fluoropolymer based spin based spin-on dielectric was employed for adhesive wafer bonding, which provides a breakdown voltage of 5.5 MV/cm and can be considered as an additional isolation layer. One side of their proposed transducer acts as the Rx and the other side as the Tx. Each array is a group of CMUTs connected in parallel, making an overall single unit transducer. Bulk acoustic waves (BAW) pass through the silicon medium between the Tx and Rx. Their proposed structure is equipped with a 4.6 μm isolation layer plus a 3 μm bonding isolation barrier. These provide for a high isolation voltage through these high dielectric insulators.

However, one drawback with this back-to-back bonded structure is that it needs to be wire-bonded on both sides. Another drawback is that the whole structure (consisting of a two back-to-back bonded die) is representative of only one channel. CMUT designs have been presented to increase the energy transfer from Tx to Rx by increasing the number and level of reflected waves. However, a high DC bias voltage (120 V) is required within CMUT devices which is, itself a significant risk for those portions of the SiP that are sensitive to voltage, electrostatics, etc.

Accordingly, it would be beneficial to provide circuit designs that provide adequate Tx and Rx isolation without the above-mentioned drawbacks.

### SUMMARY OF THE INVENTION

It is an object of the present invention to mitigate limitations within the identified prior art relating to digital isolators and more particularly to methods and devices for implementing digital isolators employing stackable multi-channel MEMS-based acoustic transmitters and receivers.

In accordance with an embodiment of the invention there is provided an electrical isolator device comprising:
an upper die comprising a piezoelectric resonator for generating an acoustic signal; and
a lower die comprising another piezoelectric resonator for receiving the acoustic signal mechanically coupled to the upper die; wherein
the acoustic signal propagates through an opening formed through a substrate of the upper die below the piezoelectric resonator.

In accordance with an embodiment of the invention there is provided an electrical isolator device comprising:
a first piezoelectric resonator for generating an acoustic signal forming part of a die;
a second piezoelectric resonator for receiving the acoustic signal forming part of a die; and
a series of trenches etched into a surface of the die; wherein
the series of trenches are disposed between the first piezoelectric resonator and the second piezoelectric resonator to form an acoustic channel which provides for guiding of the acoustic waves generated by the first piezoelectric resonator to the second piezoelectric resonator across the surface of the die.

In accordance with an embodiment of the invention there is provided an electrical isolator device comprising:
a first piezoelectric resonator for generating a bulk acoustic wave (BAW) forming part of a die; and
a second piezoelectric resonator for receiving the BAW forming part of another die.

According to another embodiment, there is a piezoelectric MEMS-based digital isolator structure wherein air (or another gas within the SiP) is employed as the transmission medium and where silicon openings within the MEMS die can contain such air or another gas; and a two-and-a-half dimension (2.5D) structure to assemble and package the inventive digital isolator with multiple Tx-Rx channels on the same substrate.

Whilst the following description with respect to embodiments of the invention is presented through a front-to-back stacking architecture of piezoelectric transducers with through silicon openings fabricated with a commercial PiezoMUMPs process it would be understood to one skilled in the art that alternate manufacturing processing methodologies and/or stacked transducer architectures may be employed without departing from the scope of the invention.

Other aspects and features of the present invention will further be described in the following detailed description and accompanying figures.

### BRIEF DESCRIPTION OF THE DRAWINGS

Embodiments of the present invention will now be described, by way of example only, with reference to the attached Figures, wherein:

FIG. 1 depicts a digital isolator, according to an embodiment of the invention, having stacked MEMS based acoustic transmitter and receiver elements;

FIGS. 2A and 2B depict plan and cross-sectional views of a digital isolator based upon a 3×3 array of channels, each with a specific frequency, exploiting stacked MEMS-based acoustic transmitters and receivers, according to an embodiment of the invention;

FIG. 3 depicts acoustic wave behaviour within through silicon openings within a MEMS based acoustic transmitter forming part of a stacked MEMS based acoustic transmitter and receiver element, according to an embodiment of the invention;

FIG. 4 depicts temporal plots of received acoustic signals through conical shaped and straight sided through silicon openings within a MEMS based acoustic transmitter forming part of a stacked MEMS based acoustic transmitter and receiver element, according to an embodiment of the invention;

FIG. 5 depicts the effect of varying through silicon opening diameter of a stacked MEMS based acoustic transmitter and receiver element, according to an embodiment of the invention;

FIG. 6 depicts another digital isolator, according to an embodiment of the invention, having stacked MEMS based acoustic transmitter and receiver elements;

FIG. 7 depicts yet another digital isolator, according to an embodiment of the invention, having stacked MEMS based acoustic transmitter and receiver elements with acoustic reflectors within through silicon openings;

FIG. 8 depicts yet another digital isolator, according to an embodiment of the invention, exploiting laterally disposed MEMS based acoustic transmitter and receiver elements;

FIG. 9 depicts conceptual cross-section of side-by-side digital isolator structures according to embodiments of the invention exploiting on-die and on-ceramic configurations;

FIG. 10 depicts top and cross-sectional views of a toroid-based disk resonator according to an embodiment of the invention as employed within side-by-side digital isolator structures according to FIG. 9;

FIG. 11 depicts schematically a definition of “same structure” in terms of shared area of their resonance frequency responses, velocity or displacement amplitude versus frequency change;

FIG. 12 depicts simulation and measurement results of the impact of trench aspect ratio variations the resonant frequency of toroid resonators according to the design depicted in FIG. 10;

FIG. 13 depicts a test bench schematic and measurement technique for toroid resonators according to the design depicted in FIG. 10;

FIG. 14 depicts a test die comprising multiple toroid resonators according to the design depicted in FIG. 10 addressed by rows and columns;

FIG. 15 depicts photographs showing the geometrical measurements of resonators and the silicon-on-insulator material quality;

FIG. 16 depicts the feed-through by measuring the velocity amplitude in mm/s for each resonator of a die according to that of FIG. 14 where one resonator is excited as transmitter;

FIG. 17 depicts exemplary results for a die according to that of FIG. 14;

FIG. 18 depicts an on-ceramic transducer according to the concept depicted in FIG. 9 on a low temperature cofired ceramic substrate with a 200 μm ceramic wall between the two toroid resonators, as transmitter and receiver;

FIG. 19 depicts laser measurements of mechanical vibration of one Tx resonator in response to an electrical burst input showing the multiple regions of charging, steady-state and discharging and a response without a steady-state region; and

FIG. 20 depicts laser measurements of mechanical vibration highlighting the acoustic-based delays of the transmitted signal within the transmitter resonator of the die and the received signal in the receiver resonator with three delays of t1, t2, and t3 identified.

### DETAILED DESCRIPTION

The present invention is directed to digital isolators and more particularly to methods and devices for implementing digital isolators employing stackable multi-channel MEMS based acoustic transmitters and receivers.

The ensuing description provides representative embodiment(s) only, and is not intended to limit the scope, applicability or configuration of the disclosure. Rather, the ensuing description of the embodiment(s) will provide to those skilled in the art with an enabling description for implementing an embodiment or embodiments of the invention. It is understood that various changes can be made in the function and arrangement of elements without departing from the spirit and scope as set forth in the appended claims. Accordingly, an embodiment is an example or implementation of the inventions and not the sole implementation. Various appearances of “one embodiment,” “an embodiment” or “some embodiments” do not necessarily all refer to the same embodiments. Although various features of the invention may be described in the context of a single embodiment, the features may also be provided separately or in any suitable combination. Conversely, although the invention may be described herein in the context of separate embodiments for clarity, the invention can also be implemented in a single embodiment or any combination of embodiments.

Reference in the specification to “one embodiment”, “an embodiment”, “some embodiments” or “other embodiments” means that a particular feature, structure, or characteristic described in connection with the embodiments is included in at least one embodiment, but not necessarily all embodiments, of the inventions. The phraseology and terminology employed herein is not to be construed as limiting but is for descriptive purposes only. It is to be understood that where the claims or specification refer to “a” or “an” element, such reference is not to be construed as there being only one of that element. It is to be understood that where the specification states that a component feature, structure, or characteristic “may”, “might”, “can” or “could” be included, that particular component, feature, structure, or characteristic is not required to be included.

Reference to terms such as “left”, “right”, “top”, “bottom”, “front” and “back” are intended for use in respect to the orientation of the particular feature, structure, or element within the figures depicting embodiments of the invention. It would be evident that such directional terminology with respect to the actual use of a device has no specific meaning as the device can be employed in a multiplicity of orientations by the user or users.

Reference to terms “including”, “comprising”, “consisting” and grammatical variants thereof do not preclude the addition of one or more components, features, steps, integers or groups thereof and that the terms are not to be construed as specifying components, features, steps or integers. Likewise, the phrase “consisting essentially of”, and grammatical variants thereof, when used herein is not to be construed as excluding additional components, steps, features integers or groups thereof but rather that the additional features, integers, steps, components or groups thereof do not materially alter the basic and novel characteristics of the claimed composition, device or method. If the specification or claims refer to “an additional” element, that does not preclude there being more than one of the additional element.

Within the following description various MEMS based solutions to provisioning a stacked acoustic transmitter and receiver pair or arrays of stacked acoustic transmitter and receiver pairs are described with respect to implementing a digital isolator within electronic circuits. These MEMS based solutions employ silicon as the structural layer within the MEMS based acoustic transmitter and receiver elements. However, it would be understood to one of skill in the art that other materials may be employed to provide the structural layer where the other material is selected from the group consisting of silicon dioxide, silicon nitride, silicon oxynitride, carbon, aluminum oxide, silicon carbide, and a ceramic. A ceramic may include, but not be limited to, barium titanate, silicon aluminum oxynitride, zinc oxide, zirconium dioxide and titanium carbide. With such alternate structural layers either their processing is compatible with the remainder of the manufacturing process or the overall manufacturing process is adapted to suit.

Within embodiments of the invention the inventive digital isolator(s) employing MEMS based stacked acoustic transmitter and receiver pairs may be monolithically integrated within an analog and/or digital circuit employing the digital isolator(s). Within other embodiments of the invention the inventive digital isolator(s) employing MEMS based stacked acoustic transmitter and receiver pairs may be hybridly integrated with the analog and/or digital circuit employing the digital isolator(s). Within other embodiments of the invention the inventive digital isolator(s) employing stackable MEMS based acoustic transmitter and receiver pairs may be monolithically integrated with part of the analog and/or digital circuit employing the digital isolator(s) or hybridly integrated with part of the analog and/or digital circuit employing the digital isolator(s).

Within the following description there is presented designs for:
a piezoelectric MEMS-based digital isolator structure wherein air (or another gas within the SiP) is employed as the transmission medium and where silicon openings within the MEMS die are formed to contain the air; and
a two-and-a-half dimension (2.5D) structure to assemble and package the inventive digital isolator with multiple Tx-Rx channels on the same substrate.

Whilst the following description with respect to embodiments of the invention is presented through a front-to-back stacking architecture of piezoelectric transducers with through silicon openings fabricated with the commercial PiezoMUMPs process it would be recognized to one of skill in the art that alternate manufacturing processing methodologies and/or stacked transducer architectures may be employed without departing from the scope of the invention.

Any reference within this specification with respect to any particular application of the novel digital isolators employing MEMS based acoustic transmitters and receivers with respect to SiPs and/or their use within any specific application are for illustrative purposes only. The scope of the inventive concept being defined by the claims.

Whilst embodiments of the invention are described and presented with respect to an air-based acoustic transmission between the Tx and Rx elements it would be understood that within other embodiments of the invention a fluid may be employed such as a gas or liquid providing the appropriate dielectric and non-conductive electrical properties to electrically isolate the Tx and Rx sides of the novel designs.

Whilst embodiments of the invention this fluid may be within the overall volume of the SiP or other packaged environment within which the novel digital isolators employing MEMS based acoustic transmitters and receivers are disposed it would be understood that within other embodiments of the invention the novel digital isolators employing MEMS based acoustic transmitters and receivers may be locally sealed with the fluid. Within some embodiments of the invention this “sealing” may be by forming other structures upon the Tx and/or Rx die to encapsulate them.

Whilst embodiments of the invention are described and presented with respect to ultrasound acoustic signals it would be understandable that within other embodiments of the invention acoustic or infrasound signals may be employed. Within other embodiments of the invention bulk acoustic wave signals may be employed.

### 1. Vertical Digital Isolators

### 1A: Air-Based Transducer Structure

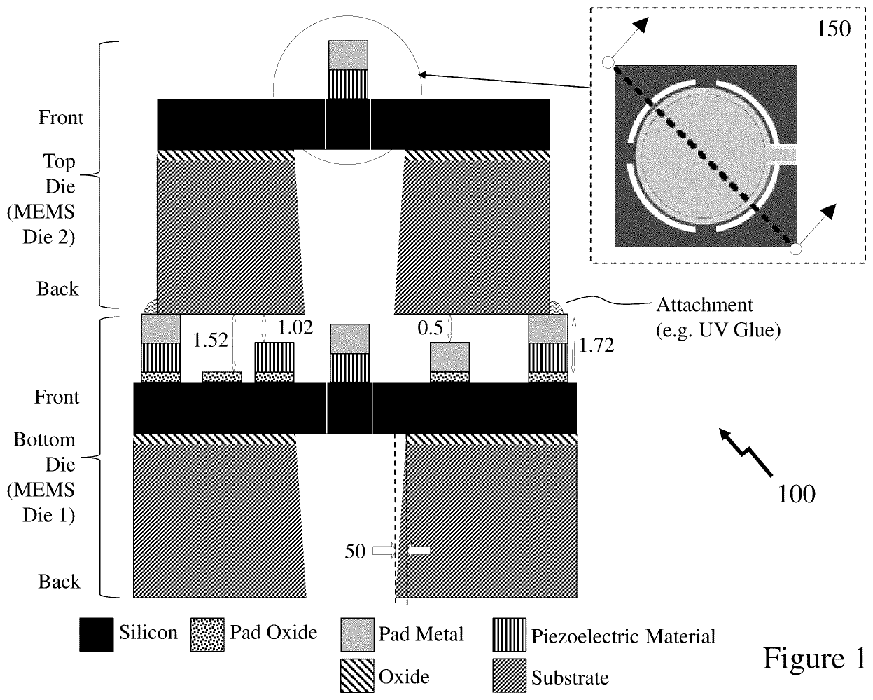

Within the PiezoMUMPs commercial MEMS process the fabrication process for a resonator starts with depositing a piezoelectric layer on top of a silicon layer. A metal layer is stacked onto the surface of the piezoelectric material. Electrical connections for exciting the piezoelectric material are applied on the silicon on the bottom and metal on the top. When the top structure of the die is completed, the surface is covered with a protection material and then trenches are etched into the backside of the die. FIG. 1 depicts a digital isolator according to an embodiment of the invention exploiting stacked MEMS based acoustic transmitter and receiver in Cross-Sectional View 100 and detailed Plan View 150. The dimensions within Cross-Sectional View 100 being in microns (μm).

An air-based silicon opening is possible through the trench formed within the substrate. This structure provides a two-sided vertical ultrasound transducer. The two-sided transducer enables the assembly of the final device either back-to-back, back-to-front, or front-to-front. Moreover, the movement of the resonator generates ultrasound waves within the opening. The produced ultrasound wave is damped first by passing through the air and then by impacting the Rx's piezoelectric layer therein transferring the physical motion of the air into a mechanical movement of the Rx piezoelectric layer thereby generating an output electrical signal.

### 1B: Fabrication

The trench under the resonator is made by deep reactive ion etching (DRIE). As a result, the trench has 50 μm radius difference between the top and bottom of the opening as depicted in Cross-Sectional View 100. Moreover, some deviations may occur in fabrication that can affect the resonance frequency of the resonator. The need for higher frequencies and also making sure to match the resonance frequency for the Tx and Rx lead to devise the methodology presented within “A novel topology for process variation-tolerant piezoelectric micromachined ultrasonic transducers” (J. Microelectromechanical Systems, Vol. 27, No. 6, pp. 1204-121, 2018). Accordingly, the proposed MEMS resonators employ a wider trench and the disk structure is patterned with four anchors on the silicon-on-insulator (SOI), such as shown in Detailed Plan View 150. In this manner it is possible to maintain the resonator frequency close to the desired resonance frequency which helps with the repeatability of the resonant structures. Moreover, another PiezoMUMPs process limitation is that the trench cannot be smaller than 200 μm. Further, the foundry design parameters restrict the design to not more than 30% of the die footprint being the trench.

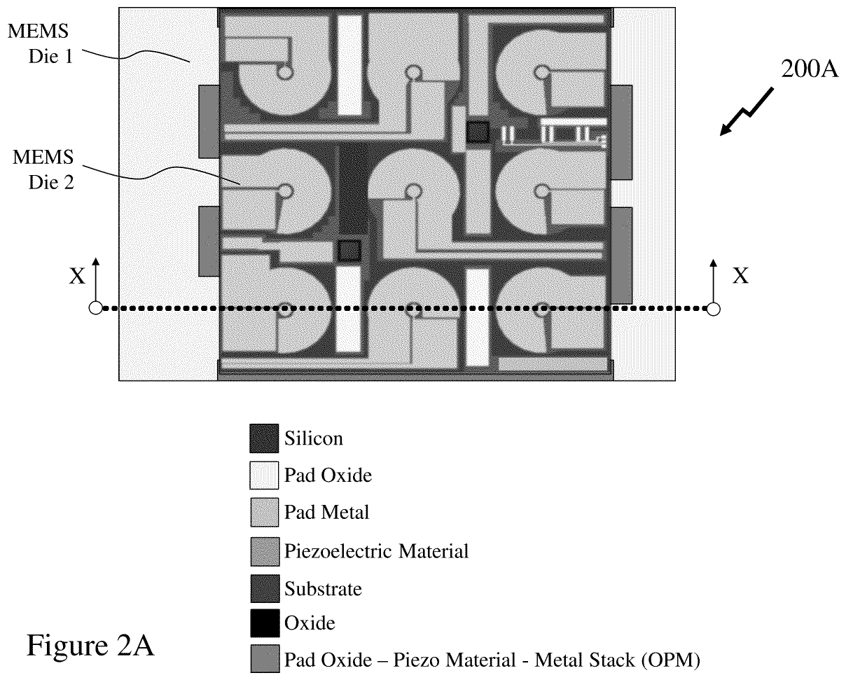

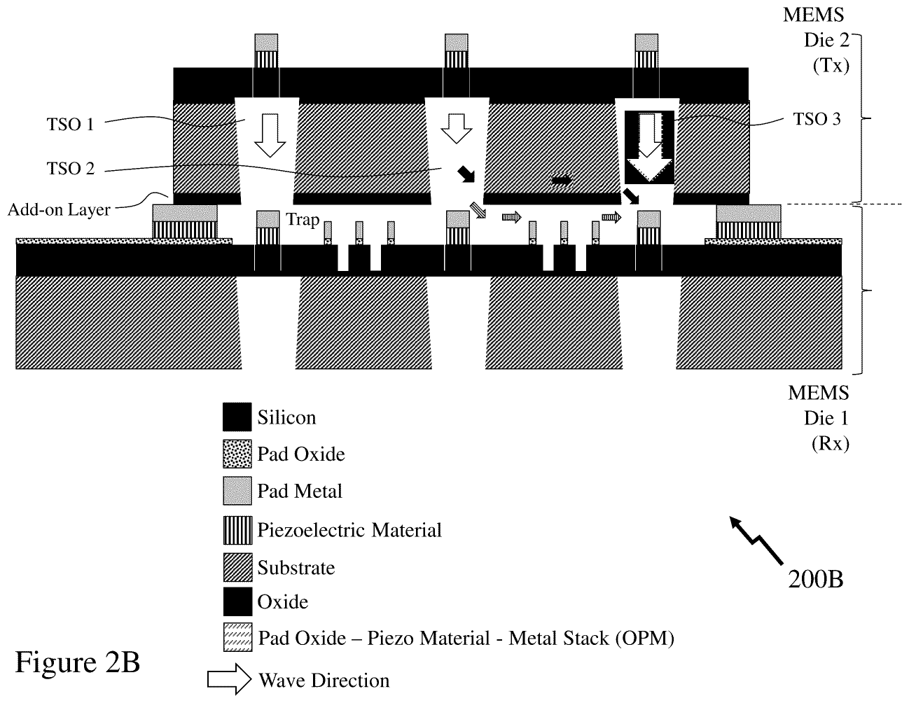

For designing multiple transducers in one die, as shown in the plan view depicted in FIG. 2A, to provide embedding of separate channels the trench can be considered as a dedicated channel by making the through silicon openings (TSOs). These TSOs can also be considered as vertical waveguides and are important as they can prevent crosstalk and make isolated channels, as shown in FIG. 2B where three TSOs are depicted in a cross-section of the 3×3 array of channels, each with a specific frequency, stacked MEMS-based acoustic transmitters and receivers according to an embodiment of the invention. Furthermore, the TSO can provide the capability of front-to-back bonding which is important for minimizing the distance between Tx and Rx elements.

In case of interference, as shown in FIG. 2B, by the small black arrows, the acoustic wave travels from the air in one TSO to silicon, passes through the silicon, and then passes from the silicon to the air in the TSO of the adjacent Rx. This route consisting of two air-silicon interfaces which dampen the acoustic wave. The other path depicted by small vertically hatched arrows consists of a 0.5 distance between the two dice and can be trapped by an oxide/metal structure with SOI holes. Most of the acoustic energy enters the substrate, some reflects back, and a small amount passes through that trap structure (i.e., the SOI hole). Accordingly, the inventive design methodology of the structures depicted in FIGS. 1 and 2B enhances the acoustic isolation from the nearby channel(s).

Accordingly, the transducer consists of both Tx and Rx elements bonded on top of each other. It would be recognised that within embodiments of the invention the Tx and Rx wafers/die are of the same design and the Tx/Rx die may be different parts of the same wafer. Within other embodiments of the invention the manufacturing process and/or design for the Tx wafer (die) and Rx wafer (die) may be different.

The bonding of two dice on top of each other can be achieved by using the thickness analysis of the different layers. Importantly, the piezoelectric layer may be employed as an insulator by placing it upon the oxide layer.

By stacking pad oxide, piezoelectric material and metal (referred to as an OPM stack or simply OPM) the thickness of this insulator is 0.2+0.5+1.02=1.72 μm within the design depicted in FIG. 1. This structure can be placed all around the die margins to make space for placing the top die on it. Electrical routings have a maximum thickness of pad oxide and metal, i.e., 0.2+1.02=1.22 μm, which is lower than the OPM thickness. The resonator is placed inside the top's opening so, the top die can be placed on the bottom of the OPM structure (distance is 0.5 μm). It may be necessary to widen the area of the OPM in order to bond the two die together with ultraviolet curing adhesive (UV-glue) as illustrated in FIG. 1. The thickness of each layer is given in Table 1 below.

TABLE 1
Materials Thicknesses in PiezoMUMPs Process

| | Pad | Piezoelectric | Pad | | | |
|---|---|---|---|---|---|---|
| Layer | Metal | Material | Oxide | Silicon | Oxide | Substrate |
| Thickness | 1.02 | 0.5 | 0.2 | 10 | 1 | 400 |
| (μm) | | | | | | |

Within other embodiments of the invention the Tx and Rx die may be attached with other means as known within the art including, but not limited to, light curing adhesive, solder and cold welding.

With respect to voltage isolation, this structure features a 1 μm isolation layer on the top die and a 0.5 μm air gap between the die. Further, in the bonding areas, there is a 1 μm isolation layer on the top die and 0.7 μm oxide plus the piezoelectric layer on the bottom die. The voltage isolation is provided through the smallest thickness, consisting of 1 μm oxide plus the 0.5 μm air gap. By just considering the silicon dioxide (SiO2, oxide) as the dielectric material, 1 μm thickness provides more than 1 kV voltage isolation. In addition, there is a bonding UV glue thickness and one add-on insulation layer (under the die on the top and as shown in FIG. 2B), to be added to the final thickness if needed for increased isolation.

### 1C: 2.5D Structure of Multi-Channel Air-Based Transducer

Considering the structure of assembling the die, it can be categorized as two-dimensional (2D), 2.5D, or three-dimensional (3D) packaging, see for example Khan et al. in “Secure interposer-based heterogenous integration” (IEEE Design & Test, Vol. 39, No. 6, pp. 156164, 2022). In the 3D structure, for inter-die connections, there is a need for through silicon vias (TSVs). Stacking Tx die (MEMS Die2 in FIGS. 1, 2A, and 2B) on top of the Rx die (MEMS Die1 in FIGS. 1, 2A, and 2B) enables this vertical integration. One advantage of this structure, especially for prototyping, is that one side wire-bonding can be used to connect both die to a common carrier. Here, the TSV is made by a TSO that connects both sides using a different physical effect, sound waves, other than metal routing. Moreover, in FIG. 2A, there is the capability of placing an ASIC die, side-by-side with this assembly. This ASIC die could include trans-impedance amplifiers (TIA), filters, and decision circuits for example. As the receiver signal is in the range of nanoamperes (nA) it is preferred to assemble the ASIC die as close as possible to the receiver die. The final structure with this approach can be categorized as 2.5D, Table 2 describes the resulting performance advantages and disadvantages of this 2.5D front-to-back assembling compared with Heller et al. in “Performance evaluation of CMUT-based ultrasonic transformers for galvanic isolation” (IEEE Trans. Ultrasonics, Ferroelectrics and Frequency Control, Vol. 65, No. 4, pp. 617-629, 2018).

TABLE 2
Inventive MEMS Acoustic Digital Isolator Element Comparison to Heller

| Parameter | This Work (Simulated) | Heller |
|---|---|---|
| Die Dimensions | 4.3 × 4.3 mm (Tx Die) | 4 × 17 mm |
| | 4.3 × 9.0 mm (Rx Die) | |
| Acoustic Signal Type | Ultrasound | BAW |
| Physical Wave Medium | Air | Silicon |
| Actuation Type | AC | AC + 120 V DC |
| Resonant Frequency | 7.5 MHz | 12 MHz |
| Rx Response Delay | 1.1 μs | N/A |
| Maximum Bit-Rate | 2.1 MHz | N//A |
| Frequency | | |
| Bonding Structure | Front-to-back | Back-to-back |
| Wire-Bonding Structure | Top | Top and bottom |
| Distance between Tx and Rx | 400 μm | 700 μm |

### 1D: Simulation Results and Comparison

Within this section, a characterization methodology by simulation is first presented. The effect of the TSO shape (ideal and real) as the main channel for propagating the ultrasound wave is investigated. To analyze the behavior of the wave inside the channel, the COMSOL multi-physics software was employed with the acoustic package. The layout of the 3×3 TSO digital isolator shown in FIGS. 2A and 2B has been sent for fabrication but has not been received at the time of filing this patent application. The parameters of the design in fabrication are assumed for simulation. The damping factor considered to be 0.5e−4 for the piezoelectric material and 1e−6 for air.

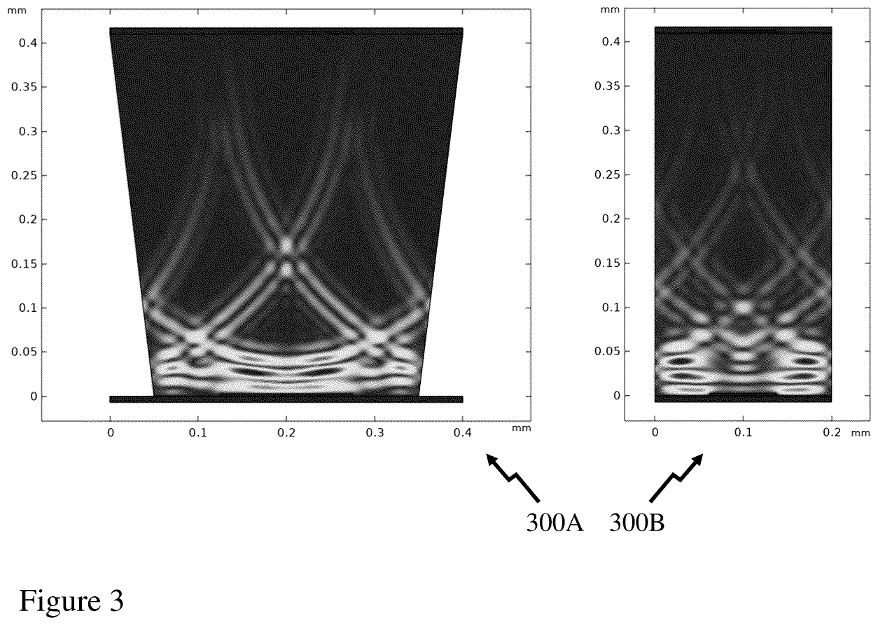

The acoustic wave propagation in one TSO was simulated with the results shown in FIG. 3. A Tx resonator on the top of the opening sends the ultrasound wave inside the channel. The bottom of the channel is the Rx piezoelectric membrane. The receiver signal is simulated for only one transducer. For a more powerful signal, there is a need to embed an array of parallel transducers of Tx and Rx resonators or to apply more energy to the Tx according to the voltage and number of excitations required in addition to providing a TIA for amplifying the receiver signal.

The acoustic waves in first and second Images 300A and 300B in FIG. 3 are illustrated at the time before it impacts into the Rx. First Image 300A being for a conical TSO and second Image 300B being for a “straight-sided” TSO (i.e., a cylindrical TSO rather than frustoconical TSO). As can be noticed the acoustic signal in first Image 300A generates three higher amplitude signals than that in second Image 300B. The moment the first acoustic wave impacts the Rx is considered the start of the receiver signal, which happens at 1.1 μs. This is representative of the delay or phase shift and relates to the characteristics of the medium, which was air in this simulation. Considering the speed of sound in air (340 m/s), it takes 1.17 μs to propagate through the 400 μm air column of the TSO. The delay difference comes from the meshing size in COMSOL. Although delay is not mentioned by Heller, as the speed of sound is higher in silicon than in air (by about 16 times), this delay for Heller is expected to be lower and the same for the maximum bit rate in Heller. In addition, considering the straight structure of the TSO in second Image 300B in FIG. 3, the concentration of the wave is distributed around the Rx rather than across as with the conical TSO in first Image 300A. Further, multiple reflected waves affect the receiver signal's period, which is longer as shown by second Curve 400B of the straight-sided TSO relative to the conical TSO in first Curve 400A.

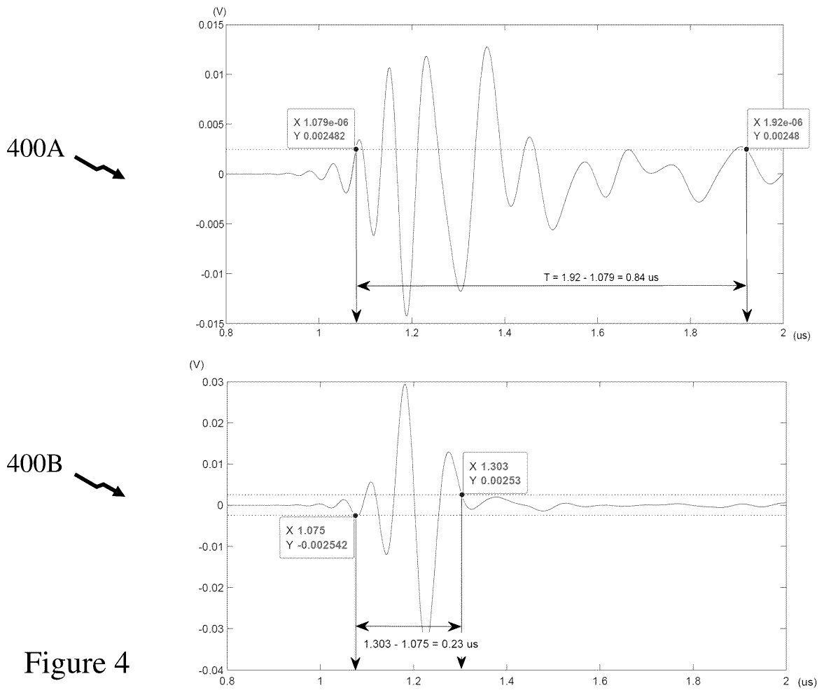

As depicted in first and second Curves 400A and 400B in FIG. 4, the pulse response of each MEMS-based Rx resonator contains several cycles that require time to be extinguished. So, for estimating the overall duration of the signal (T), there is a need to define a threshold voltage. As shown in first and second Curves 400A and 400B in FIG. 4, this threshold voltage was selected to be 2.5 mV and results in a period of 0.23 μs for the conical TSO and 0.84 μs for the straight TSO. This shows the direct effect of the TSO shape on the bit rate transmission capability of the digital isolator employing acoustic MEMS Tx and Rx elements. In the case of bit rate, considering 2×T, the bit rate is calculated as 2.1 Mbps for the conical TSO in contrast with 0.6 Mbps for the straight TSO.

The size of this 2.5D structure was 4.3 mm×9.0 mm, which is smaller than the size of the CMUT design of Heller. Further, the piezoelectric resonators do not require a high DC biasing voltage of 120 V of the CMUTs of Heller. Beneficially, the structure can be directly attached to a distributed layer substrate, such as an LTCC for example. Another important parameter is the distance between the Tx and Rx, which is decreased for this front-to-back bonding structure by approximately 43% compared to Heller.

Each channel of the structure is composed of several Tx/Rx pairs and is expected to provide superior crosstalk behavior due to the geometry of the structure compared to that within the prior art of Heller.

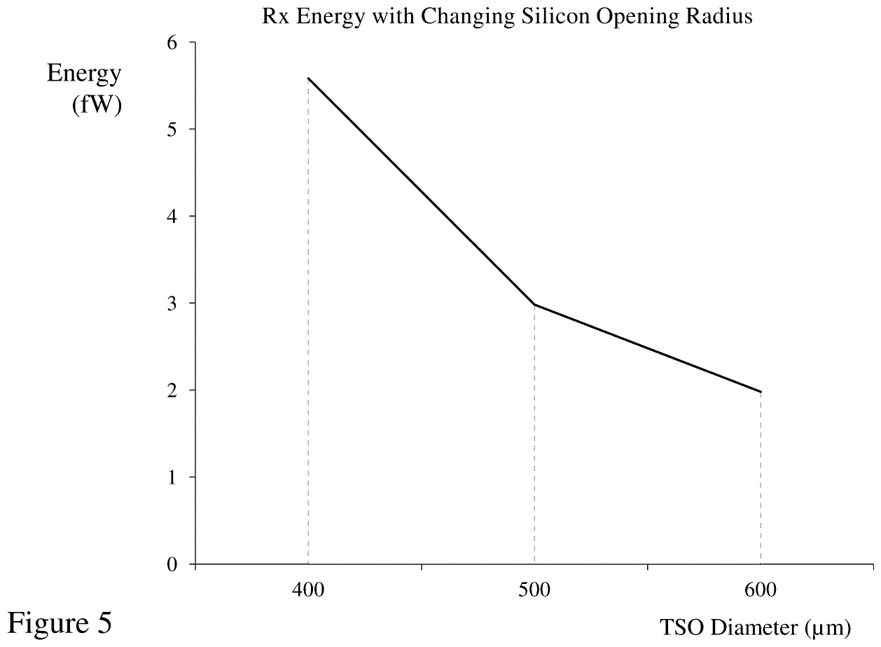

Referring to FIG. 5 there is depicted a plot received energy versus TSO radius as modeled for 3 different TSOs. The energy reduces with increasing TSO radius. Within other embodiments of the invention the TSO may be formed with a different geometry other than circular. The TSO according to embodiments of the invention may be a frustrum of a pyramid. The TSO has a first dimension (radius of cone) or first dimensions (pyramid) at a surface of the substrate closest to the piezoelectric resonator to a second dimension or dimensions at a distal surface of the substrate from the piezoelectric resonator. The second dimension or dimensions being smaller than the first dimension or dimensions. Within this specification conical is used to mean a frustum of a cone.

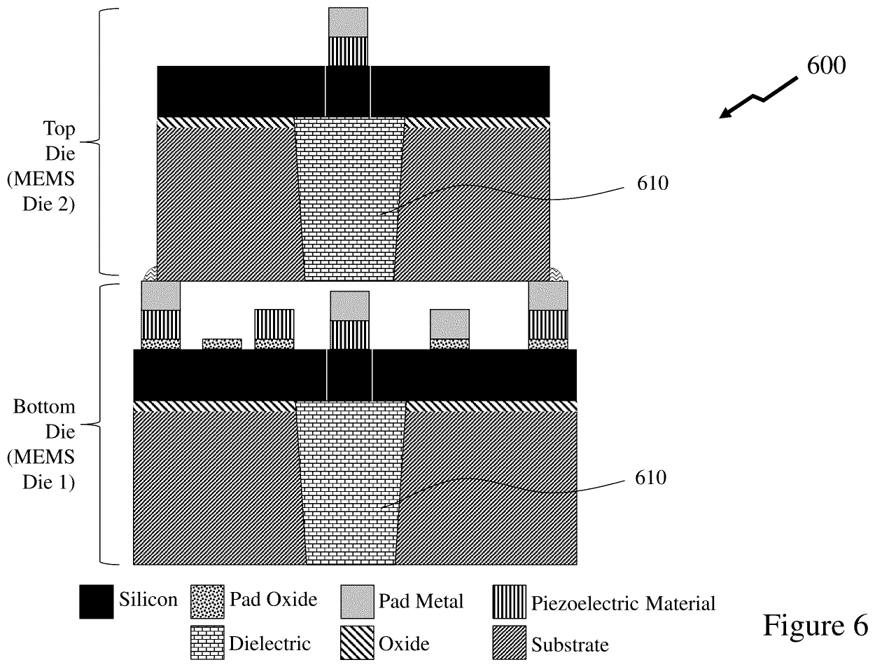

Now referring to FIG. 6 there is depicted another digital isolator, according to an embodiment of the invention, exploiting stacked MEMS based acoustic transmitter and receiver elements. The Cross-Sectional View 600 of the stacked MEMS based acoustic transmitter and receiver elements being similar to that of Cross-Sectional View 100 in FIG. 1 except that the TSO within the substrate below the MEMS resonator is now filled with a dielectric to form Resonator Column 610. The PMUT design may also be modified to a piezoelectric bulk acoustic wave (BAW) resonator (PBAWR) such that the MEMS Die 2 provides a PBAWR based transmitter and MEMS Die 1 provides a PBAWR based receiver.

The Cross-Sectional View 600 being according to an embodiment of the invention where MEMS Die 1 and MEMS Die 2 are formed through the same manufacturing sequence and may, within embodiments of the invention, be two different portions of the same processed wafer or substrate. Within another embodiment of the invention the manufacturing sequences for the MEMS Die 1 and MEMS Die 2 may be different wherein the substrate of MEMS Die 1 does not have the Resonator Column 610.

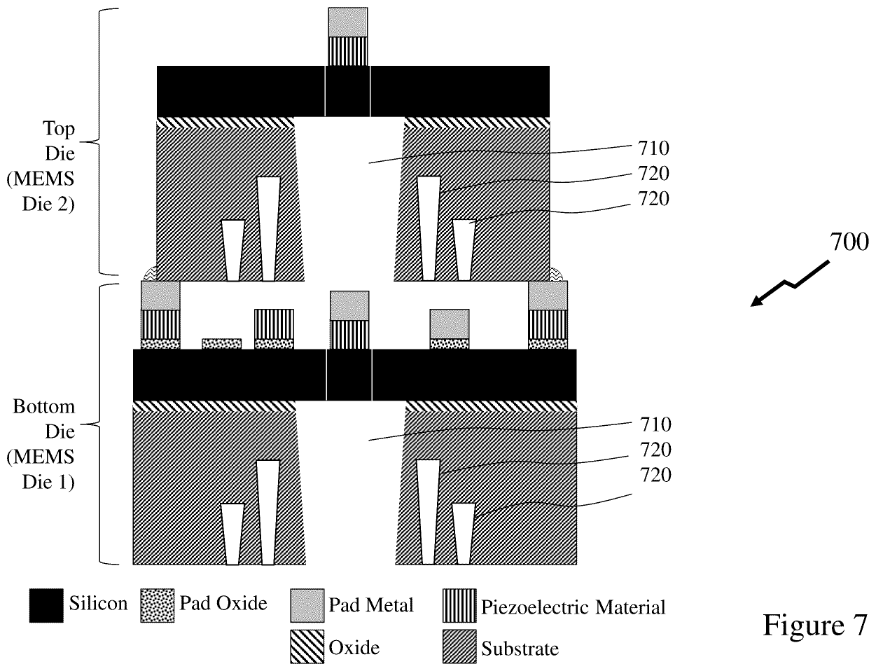

Referring to FIG. 7 there is depicted yet another digital isolator, according to an embodiment of the invention, exploiting stacked MEMS based acoustic transmitter and receiver elements with acoustic reflectors disposed with respect to the through silicon openings (TSOs) 710. The Cross-Sectional View 700 of the stacked MEMS based acoustic transmitter and receiver elements being similar to that of Cross-Sectional View 100 in FIG. 1 except that the TSO 710 within the substrate below the MEMS resonator is now surrounded by one of more Acoustic Reflectors 720 disposed radially around the TSO 710.

As depicted the Acoustic Reflectors 720 are etched into the rear surface of the substrate although within other embodiments of the invention they may be etched into the upper surface of the substrate and/or the upper and lower surfaces of the substrate. When etched into the upper surface the Acoustic Reflectors 720 may be temporarily filled with a material sacrificially removed in a subsequent processing step. Optionally, the Acoustic Reflectors 720 may be filled with another material, e.g., a metal or a dielectric.

The Cross-Sectional View 700 being according to an embodiment of the invention where MEMS Die 1 and MEMS Die 2 are formed through the same manufacturing sequence and may, within embodiments of the invention, be two different portions of the same processed wafer or substrate. Within another embodiment of the invention the manufacturing sequences for the MEMS Die 1 and MEMS Die 2 may be different wherein the substrate of MEMS Die 1 does not have the Acoustic Reflectors 720.

### 2. Lateral Digital Isolators

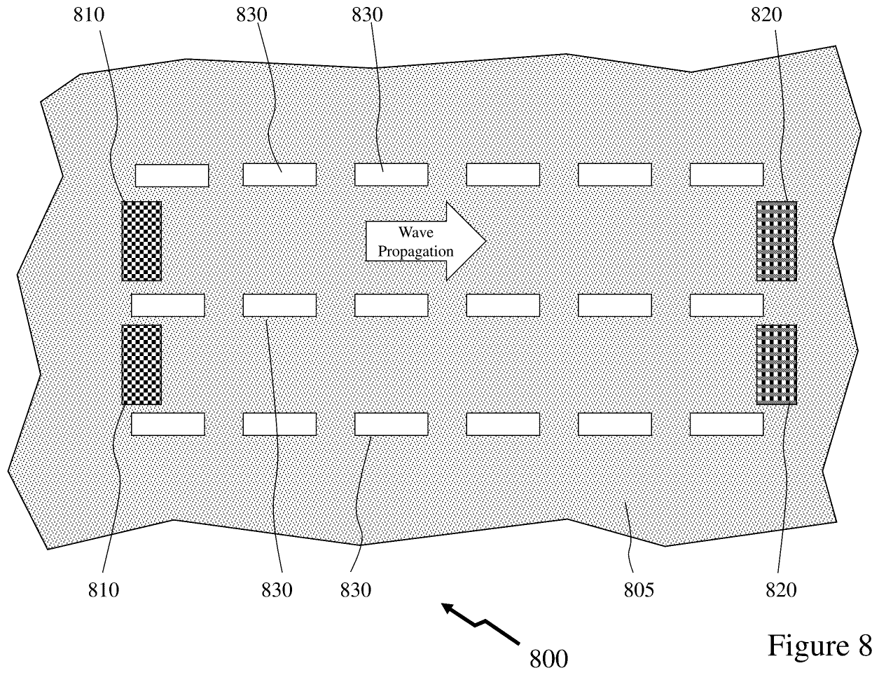

Now referring to FIG. 8 there is depicted yet another digital isolator, according to an embodiment of the invention, exploiting laterally disposed MEMS based acoustic transmitter and receiver elements. Plan View 800 depicts a Die 805 within which MEMS Transmitters 810 have been fabricated together with MEMS Receivers 820. Also disposed within the surface of the Die 805 are a series of Trenches 830. As depicted the Trenches 805 disposed between a MEMS Transmitter 810 and a MEMS Receiver 820 create a waveguide-like acoustic channel which provides for guiding of the acoustic waves generated from MEMS Transmitter 810 to MEMS Receiver 820 across the surface of the Die 805 and provides for channel-to-channel isolation between adjacent transmitter-receiver pairs. The Trenches 830 act as acoustic reflector elements. The Trenches 830 within Plan View 800 are depicted as being linearly disposed between each MEMS Transmitter 810 and its associated MEMS Receiver 820 and each being of constant width. Within other embodiments of the invention the geometry of different Trenches 830 may vary in a defined sequence from the MEMS Transmitter 810 to its associated MEMS Receiver 820. Within other embodiments of the invention the lateral position of different Trenches 830 from an axis between the MEMS Transmitter 810 to its associated MEMS Receiver 820 may vary in a defined manner from the MEMS Transmitter 810 to its associated MEMS Receiver 820.

Within another embodiment of the invention the Trenches 830 or a portion of the Trenches 830 may be filled with a material or materials, e.g., a metal or dielectric. In another embodiment of the invention the sidewalls of the Trenches 830 or a portion of the Trenches 830 may be filled with a material or materials, e.g., a metal or dielectric.

Each of the MEMS Transmitter(s) 810 and the MEMS Receiver(s) 820 are MEMS based ultrasonic transducers. Within other embodiments of the invention MEMS Transmitter(s) 810 and the MEMS Receiver(s) 820 may be infrasound transducers, acoustic transducers or bulk acoustic wave (BAW) transducers. A BAW transducer may be a thin film BAW (TFBAW) device.

For example, each of the MEMS Transmitter 810 and the MEMS Receiver 820 may be a clamped-clamped beam resonator moving laterally to generate a lateral acoustic wave within the Die 805.

### 3: Side-by-Side Digital Isolators

### 3a: Background

A common method for RF-based digital isolators, that of utilizing electric fields or magnetic flux, faces challenges distinguishing data waves from interfering electromagnetic waves due to their similar nature. Ensuring electromagnetic compatibility amidst environmental, external, internal (i.e., nearby channels), and intentional (i.e., jamming) interference is essential. To overcome this, the inventors have outlined above vertical and lateral digital isolators based upon mechanical acoustic waves, which are immune to electromagnetic interference, in a compact form factor. Microelectromechanical systems (MEMS) are employed to generate ultrasonic mechanical waves for transmitter (Tx) and receiver (Rx) interaction, utilizing moving MEMS resonators as active couplers (or transducers), unlike passive couplers in RF-based systems.

Initial devices of these designs and the side-by-side design presented below have been fabricated upon the PiezoMUMPs micro-fabrication process, provided by Science Inc., which is well-suited to fabrication of these structures, as it enables the design and fabrication of high quality resonating structures and the incorporation of piezoelectric films. In the Tx, the piezoelectric film converts electrical signals into mechanical resonator movements whilst within the Rx, the mechanical energy excites the receiving resonator, which is converted into an electrical signals for analysis, with no power supply needed for the Rx resonator during this process.

Bulk acoustic waves (BAW), generated by resonator vibrations, thereby allow for the transmission of data between the Tx and Rx, offering advantages over RF signals, including immunity to electromagnetic interference as well as high-temperature operation. The resonator's membrane vibrates solely at its eigenfrequencies preventing signal production otherwise. However, acoustic waves face challenges in speed, transmission latency, and maintaining identical resonator frequencies.

For successful data transfer, well-matched frequencies between the Rx and Tx are essential, requiring MEMS resonator devices that have identical geometries. However, MEMS fabrication processes involve lithography, masking, deposition, wet chemical etching, and deep reactive ion etching (DRIE), of multiple layers where even minimal variations cause geometrical inequalities, leading to different resonance frequencies.

One proposed solution, see Robichaud et al. “A novel topology for process variation-tolerant piezoelectric micromachined ultrasonic transducer” (J. Microelectromechanical Systems, vol. 27, no. 6, pp. 1204-1212, 2018; hereinafter Robichaud1) exploits a toroid anchor to create a fixed circle constraint for consistent frequency resonators, although some deviations remain. Difficulties in attaining exact geometries often requiring tuning. Tuning was proposed using a film, e.g. Parylene-C, on the die surface to tune the resonant frequencies, see Robichaud et al. “Frequency tuning technique of piezoelectric ultrasonic transducers for ranging applications” (J. Microelectromechanical Systems, vol. 27, no. 3, pp. 570-579, 2018), although this requires an additional post-manufacturing step and is impractical for selective tuning, for example of individual MEMS resonators within an array of MEMS resonators.

Accordingly, in order to address these issues the inventors have established, as outlined below, several novel developments including:
development of an on-die piezoelectric MEMS-based digital isolator using a silicon substrate for acoustic wave transmission;
creation of an on-ceramic piezoelectric MEMS-based digital isolator using silicon and ceramic substrates for acoustic wave transmission;
a design methodology for resonator structures using finite element analysis to simulate geometric sensitivity variations in the manufacturing process, e.g. PiezoMUMPs process; and
a formula defining same-structure resonators to better match their resonance frequencies for transducer use.

In addition to the design methodology the inventors present:
experimental results assessing the model and transducer structure behavior and performance through laser vibrometer, microscopic, and electrical measurements;
experimental measurement of feed-through in on-die implementation, demonstrating the feasibility of acoustic data transmission and reception.

### 3B: Side-by-Side Isolator Structures

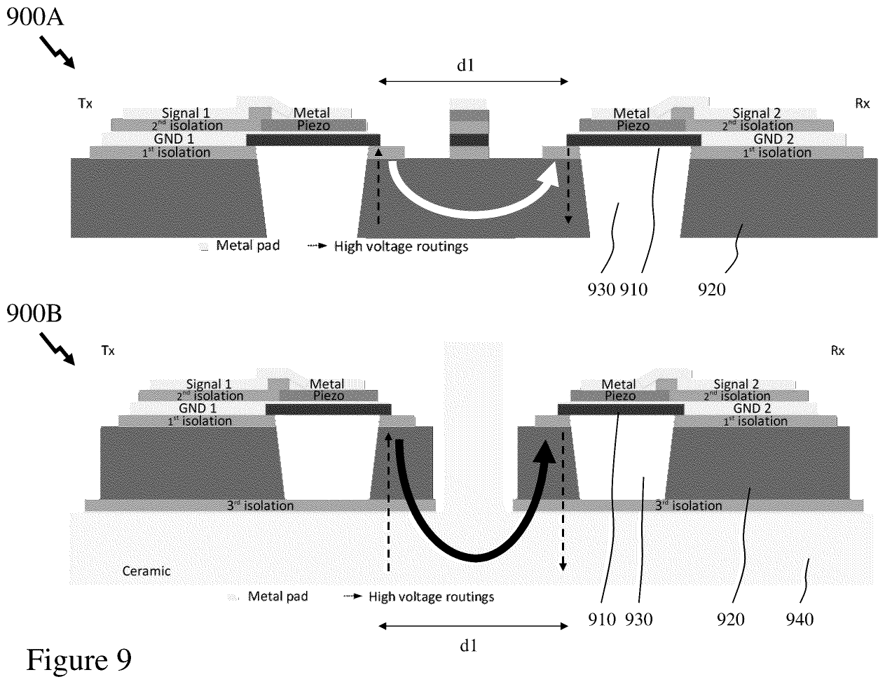

The inventors propose a digital isolator that utilizes ultrasonic acoustic wave propagation to communicate data through a substrate. The channels consist of a pair of Tx and Rx acoustic based resonators, with bulk acoustic waves (BAW) produced primarily by the resonator anchors serving as the primary communication route. Two structures are proposed, an on-die configuration where Tx and Rx transducers are on the same silicon die substrate (see first Image 900A in FIG. 9), and an on-ceramic configuration where Tx and Rx transducers are physically separated on a ceramic substrate (see second Image 900B in FIG. 9).

For both on-die and on-ceramic digital isolators, the corresponding acoustic resonators should have identical geometries to produce the same resonance frequencies. These resonators should be manufactured simultaneously on the same silicon die under identical conditions to ensure this matching. Deviations in frequency can hinder communication, as resonators respond optimally only when exposed to signals at their natural frequencies, also known as eigenfrequencies.

### 3B:A. On-Die Structure

In the on-die configuration, the silicon substrate acts as the communication route. The primary acoustic BAW wave (solid arrow in first Image 900A in FIG. 9) propagates through the silicon substrate, serving as the channel from the Tx to the Rx resonator. Waves move vertically through the air and are then converted into BAW upon impacting the trench walls, and attenuation occurs through the substrate as the BAW travel to the Rx resonator.

The manufacturing process involves several layers that contribute to the voltage isolation capacity of the on-die digital isolator. Following the high-voltage route (dotted arrows first Image 900A in FIG. 9), a 1 μm SiO2 insulation layer is deposited across the die. This side-by-side implementation features two SiO2 layers between the Tx and Rx resonators, along with the silicon substrate itself, acting as the isolating channel. Theoretically, this configuration can achieve an isolation voltage of approximately 2 kV (2 μm×1 kV/μm). This isolation is further increased by taking into account the resistive silicon semiconductor substrate that is in series in the channel.

### 3B:B. On-Ceramic Structure

In the on-ceramic configuration, the fabricated Tx and Rx resonators on the same silicon substrate are separated and deposited onto a ceramic substrate (second Image 900B in FIG. 9). The ceramic wall between them prevents a direct line of sight, enhancing high-voltage isolation due to the ceramic's high dielectric strength.

Low temperature co-fired ceramics (LTCC) may be used to miniaturize systems, especially in power solutions using systems in package (SiP). The high sound velocity the LTCC material further aids in spreading the acoustic waves.

Following the high-voltage route (dotted arrows in second Image 900B in FIG. 9), both resonators can be further isolated with additional dielectric layers (third isolation layer in second Image 900B in FIG. 9), such as a high breakdown voltage polymer used for adhesive wafer bonding (e.g. AL-X2000), capable of 5.5 MV/cm.

This configuration allows for stronger voltage isolation by adjusting the thickness of insulating materials and enables different isolations for each channel, or setting the distance between the Rx and Tx in order to exploit the voltage isolation properties of the ceramic substrate (carrier). Another advantage is the lack of alignment necessity due to BAW wave expansion throughout the substrate.

Both on-die and on-ceramic implementations depicted in first and second Images 900A and 900B respectively can house multiple distinct channels in a single digital isolator pack by placing resonators with various resonance frequencies on the same substrate without interference. These designs, using sound waves rather than electromagnetic waves, offer a significant advantage in avoiding electromagnetic interference.

Within both first and second Images 900A and 900B respectively there are depicted the Membrane 910 of the MEMS resonators, the silicon substrate 920 and the Trenches 930 formed to allow the Membrane 910 to move. In second Image 900B in FIG. 9 the Ceramic 940 is depicted below the silicon substrates of the MEMS resonator die.

### 3C: Resonator Design and Frequency Sensitivity Analysis

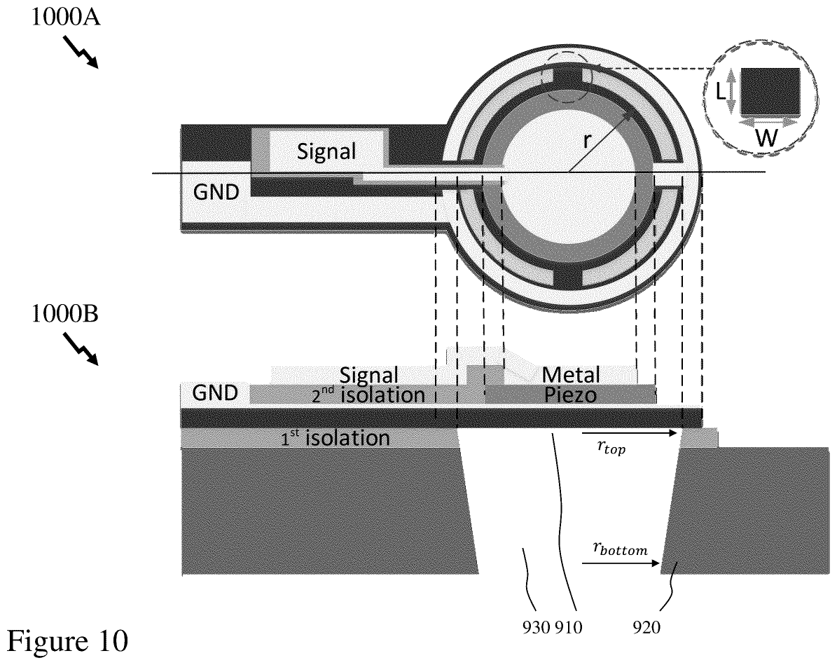

Within the following description devices according to embodiments of the invention are described and results presented for devices fabricated with the PiezoMUMPs process, which is a multi-layer fabrication process that stacks five layers on top of one another. The structure of a resonator using the PiezoMUMPs process is illustrated in FIG. 10 whilst Table 3 outlines the Layer thickness deviations and trench aspect ratio differences (in μm) according to the PiezoMUMPs manufacturing handbook.

TABLE 3
Layer thickness deviations and trench aspect ratio differences
(in μm) according to the PiezoMUMPs manufacturing handbook

| Layer/Process | Minimum | Typical | Maximum |
|---|---|---|---|
| Polysilicon | 9 | 10 | 11 |
| Substrate | 395 | 400 | 405 |
| Pad Metal | 0.47 | 0.52 | 0.57 |
| SiO2 Oxide | 0.95 | 1.00 | 1.05 |
| Trench Aspect Ratio | r_{bottom} | r_{bottom} | rₜₒₚ = r_{bottom} + 50 |
| (Second Image 1000B) | | | |

Referring to second Image 1000B in FIG. 10 the substrate is a 400 μm silicon layer (Silicon 920) covered with a 1 μm silicon oxide (SiO2) layer (first isolation in second Image 1000B) and a 10 μm polysilicon layer (Membrane 910 in second Image 1000B), forming a silicon-on-insulator (SOI) structure. This SOI serves as the base for the resonator membrane, with the other layers stacked on top. The polysilicon surface acts as the first electrical connection, while the second electrical connection, including interconnect and pads, is made by the metal layer (identified as signal/metal/GND in second Image 1000B). Another oxide layer (second isolation in second Image 1000B) isolates these two conductive layers. The key step in producing a resonator using PiezoMUMPs is sandwiching a piezoelectric layer between metal and polysilicon layers.

After the top structure of the die is completed, a protective substance is applied to secure the surface while openings in the silicon substrate (i.e., Trench 930) are etched onto the backside. These trenches allow release of the silicon membrane for movement. The aspect ratio of the trench is specified in the manufacturing handbook, with variations up to 50 μm (rtop=rbottom+50 μm). Each manufacturing process run results in layer size and thickness tolerances, as outlined in Table 3. Table 3 highlights not only the aspect ratio variation of a trench but also the thickness variations of different layers that can occur during each manufacturing process, showing the minimum and maximum deviations from the prescribed design values.

These geometrical differences from one fabrication run to another are critical for ensuring consistent resonator performance. Within this section first reviews previous research on determining the resonance frequency of disk resonators while accounting for anchor effects. The constraints of the manufacturing technique and their impact on resonance frequency are investigated, and a sensitivity parameter is provided. Simulations are conducted using the COMSOL multi-physics software.

3C:A. Review of Toroid-Type Disk Resonator Fabricated with PiezoMUMPs

The aspect ratio variation of the trench as previously stated alters the anchored geometries of the resonator, resulting in varying resonance frequencies. A novel disk anchoring topology utilizing the toroid technique was proposed in Robichaud1 where the method establishes a simple disk-shaped structure anchored to a toroid shape, thereby reducing resonant frequency variations due to trench aspect ratio variations. The geometry and materials used for the resonator affect its resonance frequency. The PiezoMUMPs process, a multi-layer process, involves each layer (n) with distinct physical characteristics influencing the membrane's mechanical bending. The neutral plane (Zₙₚ) calculation, which considers Young's modulus (Yₙ) and Poisson's ratio (vₙ) for each layer, is crucial for computing flexural rigidity (D) and is given by Equation [1].

$${Z}_{np} = \frac{1}{2} \frac{{\sum }_{n} ( {Y}_{n} ( {h}_{n}^{2} - {h}_{n - 1}^{2} ) / ( 1 - {v}_{n}^{2} ) )}{{\sum }_{n} ( {Y}_{n} ( {h}_{n} ) / ( 1 - {v}_{n}^{2} ) )} \qquad ( 1 )$$

This neutral plane calculation directly influences the computation of flexural rigidity (D). Given the n stacked layers, the density (p) and thickness (hₙ) of each layer, specify the mass per unit area (μ) and flexural rigidity. The fundamental resonance frequency f₀ of a toroid-shaped disc resonator with radius r is given by Equation (2).

$${f}_{0} = \frac{{λ}^{2}}{2 π {r}^{2}} \sqrt{\frac{D}{μ}} \sqrt{\frac{NxW}{2 π ( r + L )}} \qquad ( 2 )$$

Within Equation (2), λ represents the mode-specific Bessel function, and the second part of the equation accounts for the number of anchors (N) and their width (W) and length (L), influencing the resonance frequency. The resonator used in this work, as depicted in first and second Images 1000A and 1000B in FIG. 10 is designed according to these constraints. Table 4 presents the dimensions of this resonator fabricated using the PiezoMUMPs process.

TABLE 4
Characteristics of the toroid-based disk resonator used
for simulations and fabrication.

| | Symbol | 15 Dice | A3 | A1 | B3 |
|---|---|---|---|---|---|
| Parameter | (1) | (2) | (3) | (3) | (3) |
| Membrane Radius | r | 100 | 90 | 80 | 70 |
| (μm) | | | | | |
| Number of Anchors | N | 4 | 4 | 4 | 4 |
| Anchor Width (μm) | W | 40 | 40 | 40 | 40 |
| Anchor Length (μm) | L | 10 | 15 | 18.5 | 15 |
| Trench Radius (μm) | Itop | 120 | 115 | 115 | 100 |

Note 1:
See first Image 1000A in FIG.10.
Note 2:
(A(4, 5), B(1, 4, 5), C(1-5), D(1-5)) in FIG. 14.
Note 3:
FIG. 14

The mathematical description of resonance frequency calculation provided here considers various parameters of the resonator. This design methodology helps in predicting the performance of the fabricated resonator and in understanding the impact of fabrication tolerances on resonance frequency as is discussed below.

### 3C:B. Resonance Frequency Matching

The definition of “same structure” is based on the shared area of the resonator's resonance frequency responses for velocity or displacement amplitude versus frequency change. The frequency response curve includes resonance frequency fᵣ, bandwidth BW, and quality factor Q. The maximum amplitude occurs at fᵣ, and the bandwidth is the frequency range where the amplitude is within 70% (−3 dB) of its maximum value. The quality factor Q is defined as the resonance frequency fᵣ divided by the bandwidth BW. High Q indicates a sharper resonance frequency curve with a narrower bandwidth.

To ensure efficient data transmission, the resonance frequencies of Tx and Rx resonators should be matched or closely aligned. FIG. 10 depicts schematically the shared frequency coverage areas for three resonators: A, Tx, and B, with resonance frequencies f_{rA}, f_{rTx}, and f_{rB}, respectively.

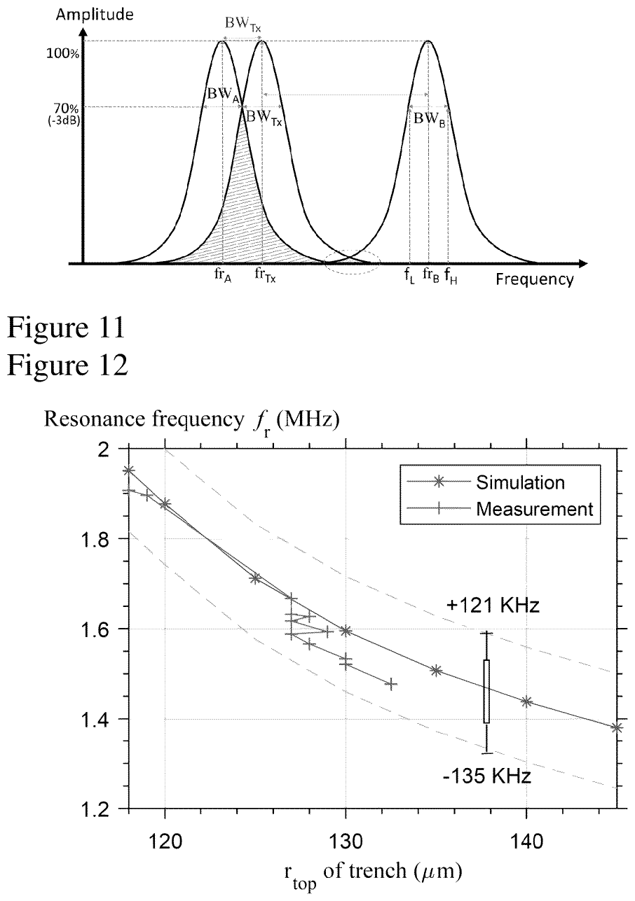

When a signal is applied to Tx, a wave is expected to be received by A and B with a displacement amplitude corresponding to their shared frequency coverage areas. The hatched areas in FIG. 11 represent the common area, where the larger it is, the more effective energy transfer happens on the resonant receiver. Resonators Tx and A can communicate successfully as they have a significant shared area (˜70%). Resonators Tx and B have a narrower shared area, reducing the efficiency of energy transfer. To select a matched-frequency receiver for the Tx resonator, the frequency difference should be within ±BW_{Tx} of f_{rTx}.

### 3C:C. Resonance Frequency Sensitivity Analysis

The importance of having matched resonance frequencies for Tx and Rx resonators as explained above and as illustrated in FIG. 11. The characteristics of the resonator fabricated with the PiezoMUMPs process are listed in Table 4. A disk resonator with four anchors into a toroid is employed to minimize manufacturing effects.

The resonance frequency is influenced by variations in the geometrical and thickness properties of each layer during the manufacturing process. Membrane and anchor dimensions, as well as the trench aspect ratio, are considered in the sensitivity analysis using COMSOL multi-physics, as shown in Table 5. These parameters include thickness tolerances from the SOI wafer and depositing processes, size variations from lithography, masking, and etching, and positioning deviations from misalignment.

| | Anchor | Anchor | Polysilicon | Trench | Trench |
|---|---|---|---|---|---|
| | Length | Width | Thickness | Aspect Ratio | Misalignment |
| Parameter | (L) | (W) | (Σ_{η} hₙ) | (rₜₒₚ - r_{bottom}) | (M) |
| $\frac{δ {f}_{r}}{{δ}_{parameter}}$ (kHz/μm) | −15 | +12 | +70 | −19.8 | −1.7 |
| Deviation | −1 to | −1 to | −1 to +1 | 0 to +50 | 0 to +5 |
| range (μm) | +3 | +3 | | | |

Table 5 includes a range of tolerances and the sensitivity parameter. Except for W and L, which were experimentally found to vary between −1 μm to 3 μm, the range is based on the PolyMUMPs manufacturing handbook. Polysilicon thickness is a critical parameter, with a tolerance of ±1 μm, causing resonance frequency deviations of up to ±70 kHz. The trench aspect ratio has a significant impact, with deviations up to 50 μm causing frequency changes of −600 kHz. The sensitivity analysis simulation in FIG. 12 shows the impact of different variations, especially the trench aspect ratio. The resonance frequency varies from 1.877 MHz to 1.380 MHZ with trench top radius deviations from 0 to 30 μm.

These significant variations highlight the challenge of finding matched frequency resonators due to manufacturing process variations.

### 3D. Application of Resonators as Transducers

### 3D:A. Test Bench Structure

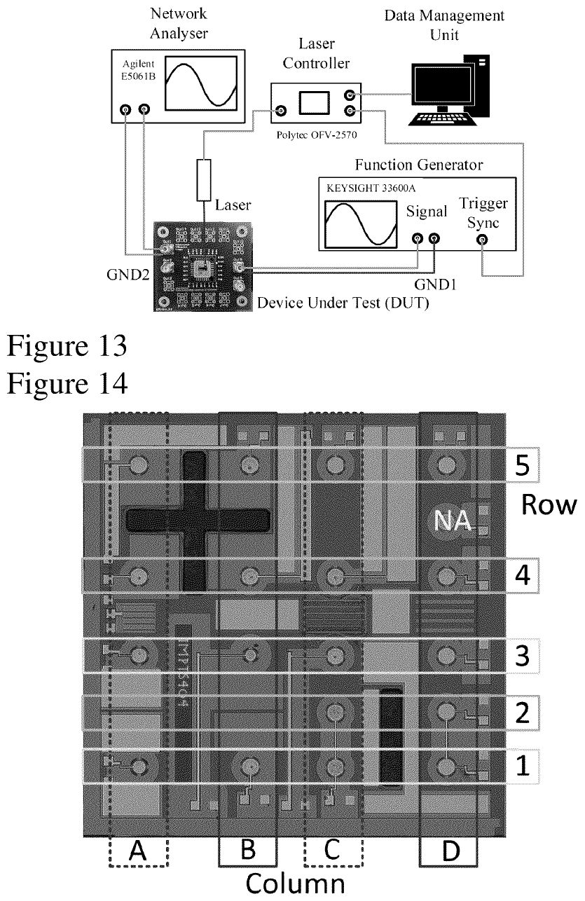

The test bench depicted in FIG. 13 was used to measure the resonance frequencies and the velocity amplitude of each resonator. The function generator generated a one-volt sinusoidal signal with a frequency equal to the resonance frequency of the corresponding resonator and was applied to the Tx resonator. The Tx resonator turns into mechanical vibration at the resonance frequency. As such, a laser vibrometer was used to measure the mechanical vibration generated by the resonator as well as all the other resonators on that die. The laser vibrometer measures the velocity amplitude (in mm/s) of the resonator's movement. The resonator's displacement (Dᵣ) is computed from Equation (3) where Av is the velocity amplitude.

$${D}_{r} = \frac{{A}_{v}}{π * {f}_{r}} \qquad ( 3 )$$

3D:B. Die-to-Die and On-Die Resonance Frequency and Q factor Measurements

Eighteen resonators were designed and fabricated using a single die as depicted in FIG. 14. Five rows and four columns (A, B, C, and D) address every resonator in the design. Fifteen of these resonators have identical geometry and the other three have different geometries each with the dimensions defined in Table 4. These fifteen resonators that are the main focus of this study have their resonance frequencies simulated, measured, and shown as fᵣ in table IV, with the exception of resonators A1, A3, and B3, which are each designed for three distinct resonance frequencies.

Experimental measurements on five dice with 15 identical designed resonators inside every single die show, as expected, different range of resonance frequencies between 1.4 MHz and 1.9 MHz as indicated in Table 6, as well as for the Q factor average from 202 to 350 (die-to-die). However, majority of the dice (Dice 3, 4, and 5) and their resonators show a range of resonance frequency around 1.6 MHz, while simulation expected for 1.877 MHz. Different frequencies are also measured for each of these 15 on-die resonators in a single die. As a result, average, standard variation, minimum and maximum of the resonance frequency and the Q factor are listed for every die in Table 6 consisting of all the 15 on-die resonators. The variation range is the difference between maximum and minimum of on-die resonators' resonance frequencies and Q factors. It shows a different range of 13 kHz to 85 kHz for fᵣ and 129 to 647 for Q, which is not predictable and demonstrate that it does not follow a specific pattern. For Die 1 and Die 2 the large standard deviation indicates that the resonance frequency is more spread or diverse, whereas for other three dice (majority of dice) the small standard deviation indicates that the resonance frequency is more concentrated.

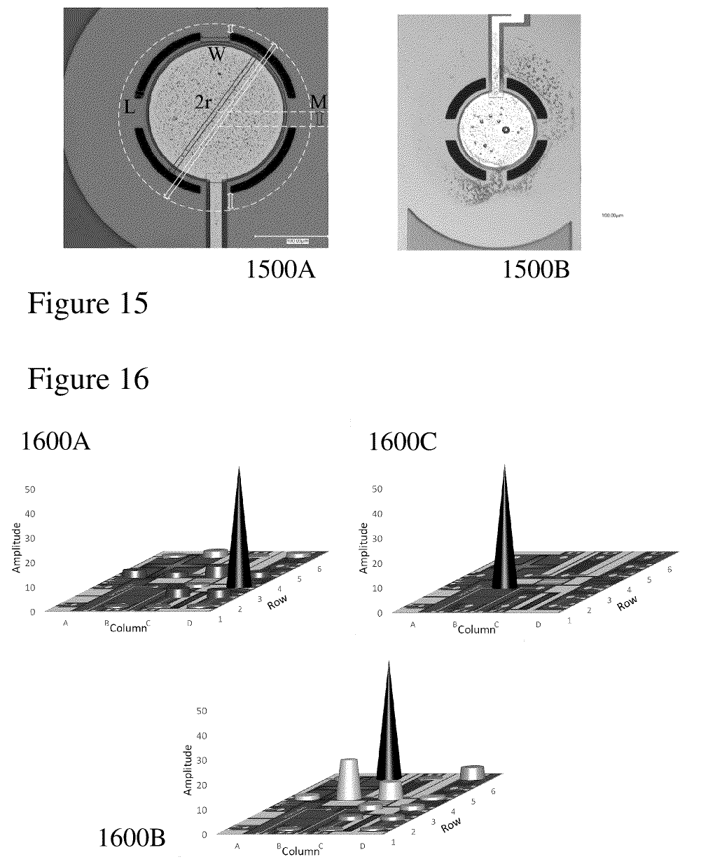

There are two explanations for this comparison listed in Table 7: one for differences in the same die and the other for die-to-die. Size, shape, thickness, and material characteristics are a few of the factors that can affect and potentially lead to changes in resonance frequency, per the Equation (2). Considering the PiczoMUMPs process, lithography and etching can decide size, misalignment and etching can change shape, and thickness of SOI can be varied in every manufacturing run in addition to the SOI quality which is also contributing to influencing the resonance frequencies of the resonators. As a result, all of these factors can cause differences from die-to-die but only SOI quality and etching are recognized as factors influencing the resonance frequency of on-die resonators. The SOI quality as shown in first and second Images 1500A and 1500B in FIG. 15, when is not properly distributed, can affect the thickness and final resonance frequency. These variations are listed in Table 7 and their effects are checked as on-die or die-to-die. This implies that if there is a problem with lithography, misalignment, or SOI thickness, it affects every on-die resonator. Nevertheless, all of these circumstances are applicable from one die to another.

TABLE 6
Summary of the Resonant Frequency Measurements on
the 16 Resonators in each of the Two Fabricated Die

| Resonance | | | | | | Simulated |
|---|---|---|---|---|---|---|
| Frequency | Die 1 | Die 2 | Die 3 | Die 4 | Die 5 | (fᵣ) |
| Average | 1.477 | 1.907 | 1.625 | 1.607 | 1.671 | 1.877 |
| (MHz) | | | | | | |
| Standard | 0.9500 | 2.6400 | 0.0039 | 0.0100 | 0.0041 | 0 |
| Deviation | | | | | | |
| (kHz) | | | | | | |
| Minimum | 1.456 | 1.883 | 1.619 | 1.583 | 1.655 | — |
| (MHz) | | | | | | |
| Maximum | 1.490 | 1.968 | 1.632 | 1.624 | 1.680 | — |
| (MHz) | | | | | | |
| Variation | 34 | 85 | 13 | 41 | 25 | 0 |
| Range | | | | | | |
| (kHz) | | | | | | |

Q Number

| | | | | | | |
|---|---|---|---|---|---|---|
| Average | 350 | 202 | 293 | 220 | 305 | — |
| Standard | 202 | 40 | 98 | 108 | 97 | 0 |
| Deviation | | | | | | |
| Minimum | 133 | 165 | 87 | 10 | 102 | — |
| Maximum | 780 | 294 | 457 | 417 | 500 | — |
| Variation | 647 | 129 | 370 | 287 | 398 | 0 |
| Range | | | | | | |

TABLE 7
Effect of Manufacturing Process Steps on Resonant
Frequency of On-Die and Die-to-Die Resonators

| | On-Die | Die-to-Die |
|---|---|---|
| Process Stage | Resonators | Resonators |
| Lithography | — | √ |
| Misalignment (Trench) | — | √ |
| Etching (Wet and Dry) | √ | √ |
| SOI Quality | √ | √ |
| SOI Thickness Variation | — | √ |

TABLE 8
Measurement Results for Three Resonators and their Effect on
the fᵣ utilizing the Sensitivity Factor presented in Table 5.

| | Die 1 | Die 2 | Die 4 | From Table 4 |
|---|---|---|---|---|
| fᵣ Average | (1.477 MHz) | (1.907 MHz) | (1.607 MHz) | (1.877 MHz) |
| 2*r | 199.4 | 199.1 | 199.4 | 200 |
| W | 40.4 | 40.5 | 40.1 | 40 |
| L | 10.5 | 10.8 | 10.1 | 10 |
| rₜₒₚ | 132 | 118 | 128 | 120 |
| rₜₒₚ − 120 | 12 | −2 | 8 | 0 |
| (Table 4) | | | | |
| Effect on fᵣ | −237.6 kHz | 39.6 kHz | −158.4 kHz | — |
| M | 10 | 0 | 1 | 0 |
| Effect on fᵣ | −17 kHz | 0 kHz | −1.7 kHz | — |

For die-to-die resonators and in connection with lithography and its influence on geometry. First Image 1500A in FIG. 15 depicts the microscopic geometrical measurements of dice for which three of them with three different range of resonance frequencies are listed in Table 8. Although their geometry differences (r, W, L) are not particularly apparent, they show some slight differences between design and manufactured dimensions as illustrated in first Image 1500A in FIG. 15 and summarized in Table 8. Albeit these sizes show some slight differences, this question is highlighted about the reason for such a big difference between (1.4 MHz to 1.9 MHz) in their resonance frequency measurements.

This question can be partially answered by examining the trench created by DRIE, which is not a completely controlled operation. The rₜₒₚ measurement of Die 1 showed a 12 μm deviation from design. According to the sensitivity factor in Table 5 this deviation is responsible for −237.6 kHz of the fᵣ difference. Along with the misalignment, it contributed −17 kHz. Thus, 63% of this significant divergence from design to manufacturing can be explained by these two components.

The data of these three dice of Table 8, along with twelve additional dice are indicated as the measurement results in FIG. 12. As depicted, these results are in agreement with those obtained by the COMSOL simulation shown in FIG. 12 particularly at higher resonance frequencies that the rₜₒₚ is closer to the design. The remaining previously listed criteria can also be used to explain the discrepancy between simulation and measurement results. By visioning and measuring the trench radius, it is feasible to categorize and identify the close resonance frequency dice for each manufacturing run. It is beneficial to perform it more quickly, without wire-bonding, and assembling the test setup.

### 3D:C. Feed-Through Study of Reciprocal Matched/Unmatched Resonance Frequencies

Having verified the electrical isolation between resonators and the electrical input signal, only one resonator is wire-bonded to be excited at its fr and acts as Tx one. All of the resonators' movements were measured with the vibrometer, displayed graphically, and listed in Tables 9A to 9C for D3, B5 and B3 resonators within the test die array whilst the displacement of the Tx resonator is shown by the tall cone in mm/s in first to third Images 1600A to 1600C for the same excited resonators respectively. Given the matched resonance frequencies, Q, and distance, it is assumed that other resonators will also vibrate, but at a reduced amplitude. Damping ratio and attenuation discussion is not within the scope of this specification. The unwanted feed-through is highlighted to be applied for digital isolator configuration. The cone head serving as the point of maximum displacement. Black cone as Tx with 48 and 50 mm/s show the maximum transmitter's range of displacement. The received signal is rated based on the maximum of this black cone's amplitude. These results are analyzed according to the main factors that impact the efficiency of transmission channels.

TABLE 9A

| | Column | | | |
|---|---|---|---|---|
| Row | A | B | C | D |
| 5 | 0.7 | 2.1 | 0.3 | 1.5 |
| 4 | 2.8 | 2.0 | 4.5 | 2.0 |
| 3 | 0.0 | 0.0 | 1.2 | 50.0 |
| 2 | NA | NA | 3.5 | 3.0 |
| 1 | 0.0 | 0.4 | 0.3 | 0.6 |

TABLE 9B

| | Column | | | |
|---|---|---|---|---|
| Row | A | B | C | D |
| 5 | 0.6 | 48.0 | 0.3 | 4.8 |
| 4 | 1.6 | 16.0 | 7.0 | 1.0 |
| 3 | 0.0 | 0.0 | 2.0 | 1.8 |
| 2 | NA | NA | 1.5 | 1.4 |
| 1 | 0.0 | 0.4 | 0.3 | 0.6 |

TABLE 9C

| | Column | | | |
|---|---|---|---|---|
| Row | A | B | C | D |
| 5 | 0.0 | 0.0 | 0.0 | 0.0 |
| 4 | 0.0 | 0.0 | 0.0 | 0.0 |
| 3 | 0.0 | 50.0 | 0.0 | 0.0 |
| 2 | NA | NA | 0.0 | 0.0 |
| 1 | 0.0 | 0.0 | 0.0 | 0.0 |

Tables 9A to 9C: Tabular View of Feed-Through by Measuring the Velocity Amplitude in mm/s for each Resonator within Die 2 for Excitation of D3, B5 and B3.

Firstly, the matched resonance frequency in a transducer configuration in a digital isolator is an essential feature for efficient data transmission. While also unmatched resonance frequencies are essential to minimize feed-through between independent transmission channels. The results depicted in FIG. 16 show both features. Resonators with closer resonance frequencies exhibit higher vibrations due to their common regions, as discussed in section 3C:B above. For instance, resonator B3 in third Image 1600C in FIG. 16, when turned into excitation, as its fr=2.955 Hz is higher than the average of 1.907 MHz (Die 2 in Table 6), the excitation measured as zero (if any exists it was negligible). The necessity of matching frequencies is also highlighted by the fact that resonators A1, A3, and B3 in FIG. 16 and Tables 9A-9C exhibit negligible vibration whereas the remaining 15 resonators with the same resonance frequency ranges, excite according to their shared frequency area.

Secondly, this transmission is a kind of bi-directional. For example, in first and second Images 1600A and 1600B in FIG. 16, resonator B5 with fᵣ=1.893 MHz, Q=193 and resonator D3 with fr=1.885 MHz, Q=170 when considering resonator B5 as the transmitter with a velocity of 48 mm/s and D3 as the receiver with a velocity of 1.8 mm/s, it is evident that when the roles of the transmitter and receiver are reversed, D3 excites with a velocity of 50 mm/s then B5 receives a velocity of 2.1 mm/s. This also providing an example of reciprocal communication. This establishes that feed-through occurs exclusively for resonators with the same geometries (same resonance frequencies).

Thirdly, the distance between Tx and Rx is also a matter for better transmitting. It indicates the damping ratio of the channel (this channel is the silicon substrate), is an additional factor for greater data transmission. This explains why even two identical resonators are unable to communicate at 100% power. In this case, take resonator B5 as Tx, the resonator B4 as Rx with frequency differences of lower 1 kHz, did not vibrate to the maximum (16 instead of 48 mm/s).

### 3D:D. On-Die/On-Ceramic Digital Isolator Configurations

The measurement results in above in Section 3D:B show an inequality for on-die and die-to-die resonators. It even exists and is diverse on a single die from one resonator to a nearly side-by-side one. This illustrates how challenging it is to recognize similar structures with nearly matching resonance frequencies, even in the same manufacturing conditions. It is evident that as a mechanical process, there is no strict 100% control over the resonators' manufacturing process. It needs for nanometer precise scale of layer-by-layer patterning of the mechanical structure of acoustic resonators. Whilst for etching, whether wet or dry, the precision is scaled to maximum of 50 μm highlights a sign of uncontrollable process. Other factors also can influence the geometries and final resonance frequency and Q factor of the resonators, as some are discussed in Section 3D:B.

By recognizing these constraints in the manufacturing process and utilizing the feed-through described in Section 3D: C it is possible to implement a digital isolator. If the design of the Tx and Rx is on the same die, it results in an on-die isolator as depicted in first Image 900A in FIG. 9. Alternatively, if they are placed separately on a different isolation material, such as a ceramic for example, it forms an on-ceramic isolator as depicted in second Image 900B in FIG. 9.

### 3D:D1 On-Die Structure:

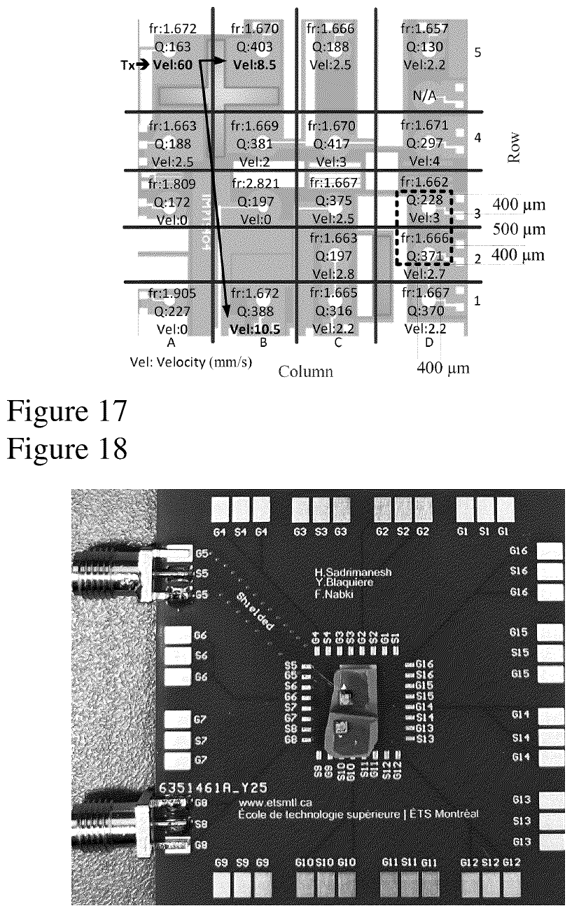

The initial concept depicted in first Image 900A in FIG. 9 uses a single silicon substrate as the substrate/carrier to implement side-by-side Tx and Rx transducers, ready to communicate in/on a single die. The silicon substrate of the die is primarily responsible for transferring the BAW waves between the two sides of the transducer. This transmission is possible by the equal resonance frequencies of both sides, as experimentally validated and quantified in this section. Considering resonator A5 in FIG. 17 as the Tx resonator then the bandwidth (BW) of every resonator is calculated using the resonator's frequency response. Resonance frequency and Q factor are correlated as BW=fr/Q where Q is the quality factor, a dimensionless parameter that describes how under-damped the resonator is. In fact, a configuration of an on-die digital isolator in first Image 900A in FIG. 9 with A5 excited is presented in FIG. 17. The fr, Q and the maximum velocity of all the resonators are measured and listed while one resonator is excited as Tx. The bandwidth area of the Tx resonator (A5) in FIG. 17 with fr=1.672 MHz and Q=160 is calculated as 10.25 kHz. Considering the concept of −3 dB for Rx with fr(Rx), as long as Equation (4) holds, they can strongly communicate (distance and damping are not part of this description). It is not a characteristic of a digital theory that it immediately damps at a given frequency; rather, in analog concepts, each hertz decreases the strength of the received signal. Again, except resonators A1, A3, and B3 with huge frequency differences, all the other resonators can communicate in mutual trend.

$$( {f}_{r ( Tx )} - \frac{B {W}_{( Tx )}}{2} - \frac{B {W}_{( Rx )}}{2} ) \leq {f}_{r ( Rx )} \leq ( {f}_{r ( Tx )} + \frac{B {W}_{( Tx )}}{2} + \frac{B {W}_{( Rx )}}{2} ) \qquad ( 4 )$$

### 3D:D2 On-Ceramic

The second concept design, introduced in second Image 900B in FIG. 9, applies a method by which resonators are cut individually from their die, each pair of resonators is selected according to their best matched fr and Q number and these are assembled in a ceramic substrate to make an on-ceramic digital isolator. FIG. 18 depicts the assembly of separated dice placed on a Low-Temperature Co-fired Ceramic (LTCC) substrate upon a test printed circuit board. As mentioned earlier, separated dice can be tested and matched in frequency and Q number, before assembling as the two sides of one digital isolator, bringing the opportunity for the selection of better-matched ones.

### 3D: E. Toroid-Based Resonator Dynamic Response Time

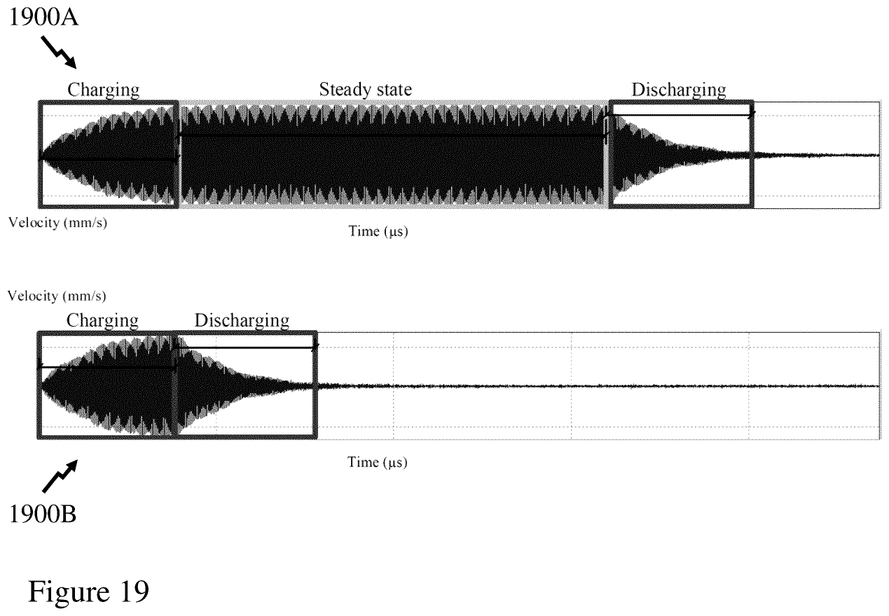

Dynamic behavior of the toroid-based disk resonator of FIG. 10 is illustrated in time domain measurements in first Image 1900A in FIG. 19. The resonator is excited by applying a sinusoidal AC signal with resonance frequency of one fundamental mode (eigenfrequency) and displacement of the disk is measured by vibrometer according to the test bench of FIG. 13. When the resonator's displacement is reaching its maximum and no longer increasing, it is referred to as steady-state. Once the resonator reaches its maximum displacement, further increasing the number of pulses has no impact on the displacement and the resonator maintains its peak. Based on the number of pulses required to reach the maximum displacement and the moment the excitation pulse is stopped, two sections of charging and discharging are defined and specified in first Image 1900A in FIG. 19. The ideal for excitation is to apply one pulse of electrical signal and reach the maximum displacement of the resonator while in reality it requires multiple pulses. The relation between the number of pulses, amplitude of the signal, and Q factor to maximum displacement is outside the scope of this specification.

The key is to figure out how to get reality as close as possible to this ideal definition. So, it is relatively straightforward to eliminate the steady-state as shown in second Image 1900B in FIG. 19. The method described by Gratuze et al. in “A nonlinear pulse shaping method using resonant piezoelectric MEMS devices” (IEEE Trans. Ultrasonics, Ferroelectrics, and Frequency Control, vol. 69, no. 4, pp. 1515-1527, 2022) may be employed to minimize and shape the resonator's exponential decay time for both charging and discharging sections. Furthermore, as a two-sided transducer, it is necessary to assess the minimal requirements for the best possible receiving signal. For example, experimentally measured that applying at least 20 pulses is adequate to turn Tx resonator (A5) of FIG. 17 into an excitation. The concern is whether this Tx excitation is adequate to stimulate the Rx resonator. The number of pulses to reach adequate displacement for the Tx and Rx membranes in a transducer configuration is different for every resonator and requires more investigation in a separate publication. In addition, the velocity of a sound wave and the acoustic impedance in the material employed for the channel between Tx and Rx are another essential characteristics that describe the dynamic response of a material.

### 3D: F. Acoustic Transducer Signal Measurements

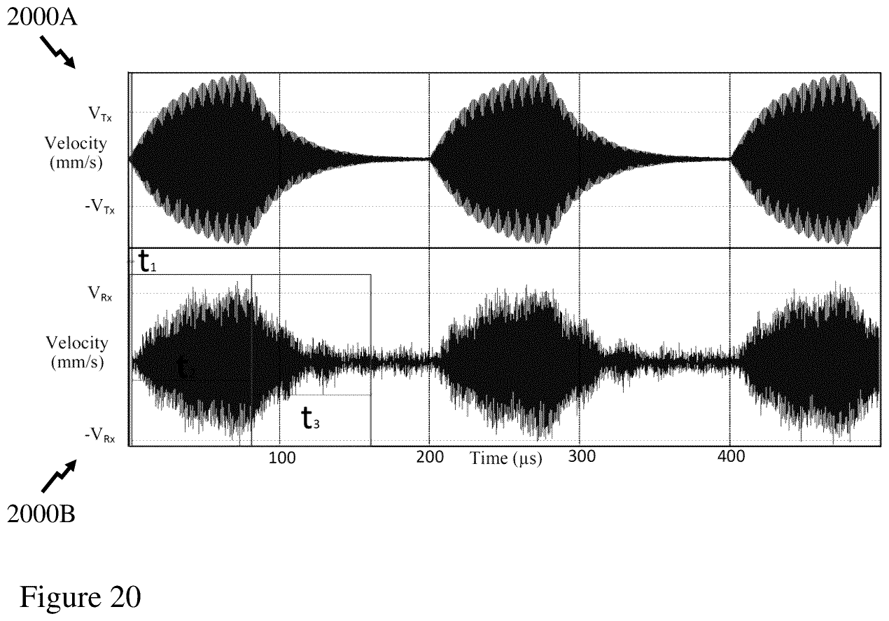

Apart from the type of assembly of digital isolators (on-die or on-ceramic), there are certain timings in the receiver section when a burst of sinusoidal waves, with a specific number of cycles and amplitude is applied to the Tx resonator. Consider a burst of 100 cycles of sinusoidal wave that is applied to the A5 resonator of FIG. 17 to be configured as Tx resonator. It is experimentally set that by this number of cycles the steady-state does not appear (second Image 1900B in FIG. 19). The excitation signal of the B1 resonator of FIG. 17 is measured as Rx resonator. The vibration of the Tx resonator (A5 in FIG. 17), and the Rx resonator (B1 in FIG. 17) depicted in first and second Images 2000A and 2000B in FIG. 20 respectively. As specified in the receiver signal of second Image 2000B in FIG. 20, there are three timings highlighted. The first, t1 is the transmission line delay associated with the path between Tx and Rx resonators in transducer configuration.

For the on-die isolator, this delay is primarily caused by the silicon substrate of the die, whereas for on-ceramic the effect of the ceramic substrate will be added to the path. The times t2 and t3 are the charge and discharge time respectively, as defined in second Image 2000B in FIG. 20. The voltage amplitude of the excitation signal, which is (0.2 V) for on-die and (5 V) for on-ceramic, is what distinguishes on-die from on-ceramic. The other distinction between on-die and on-ceramic lies in the velocity amplitude of the excitation signal, which is (VTx=40 mm/s) for on-die and (VTx=2000 mm/s) for on-ceramic depend on the distance between Tx and Rx resonators in order to receive VRx=20 mm/s by Rx resonator. In addition, the vibration of the Tx resonator (inputs S5, G5 in FIG. 18), and the Rx resonator (outputs S8, G8 in FIG. 18) is not different in shape (assume for equal Q and fr) with first and second Images 200) A and 200B in FIG. 20, except for t1 and amplitude of the velocity. Additional work may establish the correlation between the number of applied cycles, the amplitude, Q factor, and the minimum requirements for effective transmission of this transducer configuration.

### 3D: G. Acoustics Transducer Modulation Scheme

Three modulation techniques are popular in RF-based digital isolators, representing on-off-key (OOK), pulse polarity, and pulse count modulations. The OOK modulation encodes digital data as the presence or absence of a carrier wave. In its most basic form, the presence of a carrier for a given length indicates a binary one (‘1’), and its absence for the same duration represents a binary zero (‘0’). The method differs depending on the pulse polarity or pulse count modulation strategies. There is an edge-detecting circuit for the input pattern. For the pulse polarity modulation technique, each rising edge is regarded as one positive pulse and each falling edge as a negative pulse. The pulse count modulation system uses multiple pulses for the rising edge and for the falling edge. In this acoustic-based digital isolator, using several pulses to excite the resonator is treated as one unit interval to be detected as ‘1’ and absent as ‘0’. Because it does not use these pulses for edges and there is always need for multiple pulses, it can be regarded as a hybrid of pulse-count and OOK modulations. In order to filter out noise and detect the main receiving signal, one solution is to count the pulses that are produced by Rx resonator vibration. Further work will elucidate this process.

### 3E: Discussion

The majority of earlier research with RF-based (particularly CMOS) methods for achieving high-speed transfer rate and by employing electromagnetic (EM) waves through inductive or capacitive passive couplers. Accordingly, it is difficult to compare these with the acoustic devices as the concepts behind the production of MEMS acoustics-based and RF-based digital isolators are fundamentally different. Acoustic based digital isolators exhibit immunity to failure in the presence of electromagnetic interference (EMI) waves, whilst harsh acoustic interference environments may have an impact on the device's functionality.

Some size restrictions apply to the PiezoMUMPs process when creating extremely small resonators. Therefore, it is not possible to fabricate the mechanical structure for resonators with resonance frequencies in the range of GHz due to those restrictions. Final digital isolators, therefore, operate at lower speed by nature because of their mechanical design.

Breakdown voltage, also referred to as voltage isolation capability, is determined by evaluating the shortest path between the Rx pad and TX pad, as well as the features of the isolation layers in terms of their thickness and material properties. So, total isolation thickness is equal to the combination of all insulation layer thicknesses in series from Rx to Tx. As outlined with black arrows in first Image 900A in FIG. 9, in on-die implementation, two layers of (1st isolation) with 1 μm each, exist for every resonator, resulting in 2 μm oxide in total. Additionally, it is necessary to include a distance (d1=500 μm) between the Rx and Tx that include the silicon semiconductor in this computation.

For the on-ceramic implementation in second Image 900B in FIG. 9, by following the black arrow, two layers of glue with 20 μm thickness were used for attaching the die to the LTCC substrate. In addition, a 500 μm distance of dice that are already positioned in the ceramic is added. Two thicknesses of silicon dice with 800 μm in total is also added. The thickness of these multiple isolation materials used for on-ceramic breakdown voltage calculation. A 2 μm of SiO2 isolation thickness in the manufacturing process allows achieving 2 kV isolation by this PiczoMUMPs process since the breakdown voltage of SiO2 as an insulator can provide 1000 (V/μm). The ceramic is a Ferro L8 ceramic (LTCC) substrate which has a breakdown voltage of 1250 (V/25 μm). Accordingly using 500 μm of this material can provide 25 kV breakdown voltage. As illustrated in FIG. 17 the dimensions for the whole cell of Tx and Rx resonators are designed as 400 μm by 400 μm and positioned with 500 μm in distance.

Except the number of cycles, the minimum signal voltage (peak-to-peak amplitude) required for the Tx resonator to provide sufficient energy to be received at the Rx resonator is experimentally measured as 200 mV for the on-die digital isolator, whereas for the on-ceramic it is 5 V, that can be described by the channel materials. Due to variations in the substrate of the channel, the level of loss experienced also differs. Twice the thickness of silicon and glue bonding, together with one ceramic distance spacing, make up the isolation material for on-ceramic. However, there are only two silicon thickness available for on-die channel. There are benefits to utilizing a ceramic such as LTCC as a substrate, chief among them being its great dielectric capacity and high sound velocity in bulk.

Specific details are given in the above description to provide a thorough understanding of the embodiments. However, it is understood that the embodiments may be practiced without these specific details. For example, circuits may be shown in block diagrams in order not to obscure the embodiments in unnecessary detail. In other instances, well-known circuits, processes, algorithms, structures, and techniques may be shown without unnecessary detail in order to avoid obscuring the embodiments.

Implementation of the techniques, blocks, steps and means described above may be done in various ways. For example, these techniques, blocks, steps and means may be implemented in hardware, software, or a combination thereof. For a hardware implementation, the processing units may be implemented within one or more application specific integrated circuits (ASICs), digital signal processors (DSPs), digital signal processing devices (DSPDs), programmable logic devices (PLDs), field-programmable gate arrays (FPGAs), processors, controllers, micro-controllers, microprocessors, other electronic units designed to perform the functions described above and/or a combination thereof.

The foregoing disclosure of the exemplary embodiments of the present invention has been presented for purposes of illustration and description. It is not intended to be exhaustive or to limit the invention to the precise forms disclosed. Many variations and modifications of the embodiments described herein will be apparent to one of ordinary skill in the art in light of the above disclosure. The scope of the invention is to be defined only by the claims appended hereto, and by their equivalents.

Further, in describing representative embodiments of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the scope of the present invention.

What is claimed is:

1. An electrical isolator device comprising:
an upper die comprising a piezoelectric resonator for generating an acoustic signal; and
a lower die comprising another piezoelectric resonator for receiving the acoustic signal mechanically coupled to the upper die; wherein
the acoustic signal propagates through an opening formed through a substrate of the upper die below the piezoelectric resonator.

2. The electrical isolator device according to claim 1, wherein
the opening formed through the substrate is conical.

3. The electrical isolator device according to claim 1, wherein
the opening formed through the substrate is a frustum of a cone and tapers from a first dimension at a surface of the substrate closest to the piezoelectric resonator to a second dimension at a distal surface of the substrate from the piezoelectric resonator;
the second dimension being smaller than the first dimension.

4. The electrical isolator device according to claim 1, wherein
the opening formed through the substrate is a frustum of a pyramid conical and tapers from first dimensions at a surface of the substrate closest to the piezoelectric resonator to second dimensions at a distal surface of the substrate from the piezoelectric resonator;
the frustum of the pyramid is smaller at the distal surface of the substrate than at the surface of the substrate.

5. The electrical isolator device according to claim 1, wherein
the another piezoelectric resonator is disposed upon a surface of the die closest to a lower surface of the upper die.

6. The electrical isolator device according to claim 1, wherein
the opening and a region between the lower surface of the upper die and the another piezoelectric resonator are filled with a fluid.

7. The electrical isolator device according to claim 1, wherein
the opening and a region between the lower surface of the upper die and the another piezoelectric resonator are filled with a fluid;
the upper die and lower die are mechanically coupled in a manner that the opening and the region between the lower surface of the upper die and the another piezoelectric resonator filled with the fluid are sealed from the external environment.

8. An electrical isolator device comprising:
a first piezoelectric resonator for generating an acoustic signal forming part of a die;
a second piezoelectric resonator for receiving the acoustic signal forming part of a die; and
a series of trenches etched into a surface of the die; wherein
the series of trenches are disposed between the first piezoelectric resonator and the second piezoelectric resonator to form an acoustic channel which provides for guiding of the acoustic waves generated by the first piezoelectric resonator to the second piezoelectric resonator across the surface of the die.

9. The electrical isolator device according to claim 8, wherein
at least one of:
a portion of the series of trenches are filled with one or more materials; and
a sidewall of each trench is coated with one or more other materials; and
each material or other material is a metal or a dielectric.

10. The electrical isolator device according to claim 8, wherein
the first piezoelectric resonator and the second piezoelectric resonator are one of a pair of ultrasonic transducers, a pair of infrasound transducers, a pair of acoustic transducers and a pair of bulk acoustic wave transducers.

11. The electrical isolator device according to claim 8 wherein
at least one of:
the first piezoelectric resonator and the second piezoelectric resonator are a pair of thin film bulk acoustic wave transducers;
the first piezoelectric resonator and the second piezoelectric resonator are a pair of clamped-clamped beam resonators generating lateral acoustic waves within the die.

12. An electrical isolator device comprising:
a first piezoelectric resonator for generating a bulk acoustic wave (BAW) forming part of a die; and
a second piezoelectric resonator for receiving the BAW forming part of another die.

13. The electrical isolator device according to claim 12, wherein
the first piezoelectric resonator and the second piezoelectric resonator are each a resonator anchored to a toroid structure;
the resonator is disposed above a trench etched through the die.

14. The electrical isolator device according to claim 12, wherein
the die and the another die are the same die and the BAW propagates through the die.

15. The electrical isolator device according to claim 12, wherein
the die and the another die are mounted to a carrier and the BAW propagates through the die from the first piezoelectric resonator to the carrier and then through the carrier to the other die and therein to the second piezoelectric resonator.

16. The electrical isolator device according to claim 12, wherein
the die and the another die are mounted to a carrier;
a region of the carrier between the die and the other die extends upwards from the carrier to form a wall between the die and the another die;
the BAW propagates through the die from the first piezoelectric resonator to the carrier and then through the carrier to the other die and therein to the second piezoelectric resonator; and
the region of the carrier extending upwards from the carrier forming the wall extends a length of the path the BAW propagates from the first piezoelectric resonator to the second piezoelectric resonator.

17. The electrical isolator device according to claim 12, wherein
the die and the another die are mounted to a carrier and the BAW propagates through the die from the first piezoelectric resonator to the carrier and then through the carrier to the other die and therein to the second piezoelectric resonator; and
an electrical breakdown voltage between the die and the another die is increased relative to that when the die and another die are upon a common substrate within which the first piezoelectric resonator and the second piezoelectric resonator are formed.

18. The electrical isolator device according to claim 12, wherein
the first piezoelectric resonator and the second piezoelectric resonator form a transmitter-receiver pair where the first piezoelectric resonator and the second piezoelectric resonator have a defined design operating frequency;
the transmitter-receiver pair is one of a set of transmitter-receiver pairs where the; and
the defined design operating frequency for each transmitter-receiver pair of the set of transmitter-receiver pairs is different such that the set of transmitter-receiver pairs provide a set of independent electrical isolator devices.
